(19) United States
(12) Patent Application Publication
(10) Pub. No.: US 2025/0069883 A1
(43) Pub. Date: Feb. 27, 2025

(54) SELECTIVE DEPOSITION OF OXIDE MATERIAL AND A DEPOSITION ASSEMBLY

(71) Applicant: ASM IP Holding B.V., Almere (NL)

(72) Inventors: Vincent Vandalon, Heverlee (BE); Marko Tuominen, Helsinki (FI); Krzysztof Kamil Kachel, Chandler, AZ (US); YongGyu Han, Leuven (BE); Nadadur Veeraraghavan Srinath, Chandler, AZ (US); Kranthi Kumar Vaidyula, Chandler, AZ (US); Shaoren Deng, Ghent (BE)

(21) Appl. No.: 18/810,573

(22) Filed: Aug. 21, 2024

Related U.S. Application Data
(60) Provisional application No. 63/534,365, filed on Aug. 24, 2023.

(51) Int. Cl. H01L 21/02; C23C 16/04; C23C 16/40; C23C 16/455

(52) U.S. Cl. CPC H01L 21/02205; C23C 16/04; C23C 16/401; C23C 16/45553; H01L 21/02211; H01L 21/0228; H01L 21/02164

(57) ABSTRACT

The disclosure relates to methods of selectively depositing an oxide material layer on a first surface of a semiconductor substrate relative to a second surface of the same substrate, to semiconductor processing assemblies, as well as to oxide material layers, structures and devices comprising an oxide material layer deposited according to the current disclosure. In the method, an oxide material layer is selectively deposited using a first precursor and an oxygen precursor. The second surface may be passivated against deposition of oxide material.

### CROSS-REFERENCE TO RELATED APPLICATIONS

This application claims priority to and the benefit of U.S. Provisional Application No. 63/534,365, filed Aug. 24, 2023, the entirety of which is incorporated by reference herein.

### FIELD

The present disclosure generally relates to methods and assemblies for processing semiconductor substrates. More particularly, the disclosure relates to methods and assemblies for selectively depositing an oxide material on a semiconductor substrate comprising a first and a second surface.

### BACKGROUND

Semiconductor device fabrication processes generally use advanced deposition methods. Patterning is conventionally used in depositing different materials on semiconductor substrates. Selective deposition, which is receiving increasing interest among semiconductor manufacturers, could enable a decrease in steps needed for conventional patterning, reducing the cost of processing. Selective deposition could also allow enhanced scaling in narrow structures. Various alternatives for bringing about selective deposition have been proposed, and additional improvements are needed to expand the use of selective deposition in industrial-scale device manufacturing.

Oxide materials, such a silicon oxide, metal oxides and their mixtures are used in many applications, and serve various functions in semiconductor devices. For example, certain metal oxides, such as hafnium oxide, zirconium oxide, aluminum oxide and yttrium oxide may function as high k materials, as etch-stop layers or both. Silicon oxide-based materials are probably the most widely used material group in the industry, and silicon oxide, alone or in combination with one or more metals is an integral part of most semiconductor devices.

Vapor deposition techniques, especially cyclic chemical vapor deposition (cyclic CVD) and atomic layer deposition (ALD) may be used to grow oxide materials on semiconductor substrates. Typically, the deposition relies on two precursors, one of which provides the oxygen and the other the additional element, such as a metal or silicon. Depending on the exposed surfaces of a partially fabricated device, deposition of oxide material may have the disadvantage of the oxygen precursor damaging—such as through oxidizing—exposed sensitive surfaces. Therefore, softer selective deposition processes are sought after in the industry. However, development of such processes has proven to be difficult, as retaining sufficient reactivity for deposition has generally relied on reactive oxygen precursors, as selectivity may require the second precursor to have modest reactivity.

Any discussion, including discussion of problems and solutions, set forth in this section has been included in this disclosure solely for the purpose of providing a context for the present disclosure. Such discussion should not be taken as an admission that any of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter. Various embodiments of the present disclosure relate to methods of selectively depositing oxide materials on a first surface of a substrate relative to a second surface. Embodiments of the current disclosure further relate to methods of fabricating semiconductor devices, and to semiconductor processing assemblies.

Various embodiments of the current disclosure relate to vapor deposition methods and assemblies for selectively depositing oxide material layers on a substrate.

A method of selectively depositing an oxide material layer on a first surface of a substrate is disclosed. The deposition on the first surface may be performed relative to a second surface of the same substrate. The method according to the current disclosure comprises providing a substrate comprising the first surface and the second surface in a reaction chamber, and optionally providing a metal or metalloid catalyst into the reaction chamber in a vapor phase. Thereafter, a first precursor is provided in the reaction chamber in a vapor phase; and an oxygen precursor comprising a hydroxyl group is provided in the reaction chamber in vapor phase to form an oxide material layer on the first surface.

In some embodiments, the second surface comprises a passivation layer. In some embodiments, the passivation layer comprises polyimide.

In some embodiments, the first surface comprises a dielectric surface. In some embodiments, the first surface is a dielectric surface. In some embodiments, the first surface comprises silicon. In some embodiments, the first surface is a silicon-comprising dielectric surface.

In some embodiments, the catalyst is a metalloid catalyst. In some embodiments, the catalyst comprises boron. In some embodiments, the catalyst comprises silicon. In some embodiments, the catalyst comprises a metal halide, organometallic compound or metalorganic compound. In some embodiments, the catalyst is a metal catalyst. In some embodiments, the catalyst is a metal halide, organometallic compound or metalorganic compound. In some embodiments, the catalyst is a compound comprising B, Zn, Mg, Mn, La, Hf, Al, Zr, Ti, Sn, Y or Ga. In some embodiments, the catalyst comprises trimethyl aluminum (TMA), dimethylaluminumchloride, aluminum trichloride (AlCl₃), dimethylaluminum isopropoxide (DMAI), tris(tertbutyl)aluminum (TTBA), tris(isopropoxide)aluminum (TIPA), tris(dimethylamino)aluminum (TDMAA) or triethyl aluminum (TEA).

In some embodiments, the substrate is heated before providing the catalyst into the reaction chamber.

In some embodiments, the oxygen precursor comprises an alcohol comprising from 1 to 6 carbon atoms. In some embodiments, the oxygen precursor is an alcohol comprising from 1 to 6 carbon atoms. In some embodiments, the oxygen precursor comprises a secondary or tertiary alcohol. In some embodiments, the oxygen precursor is a secondary or tertiary alcohol. In some embodiments, the oxygen precursor is selected from methanol, ethanol, propan-1-ol, propan-2-ol, butan-1-ol, butan-2-ol, pentan-1-ol, iso-butanol, tert-butanol, pentan-2-ol, pentan-3-ol, ethane-1,2-diol, propane-1,2-diol, propane-1,2,3-triol, butane-1,2-diol, butane-2,3-diol, butane-1,3-diol, butane-1,4-diol, butane-1,2,3-triol, butane-1,2,3,4-tetraol, pentane-1,2-diol, pentane-1,3-diol, pentane-1,4-diol, pentane-1,5-diol, pentane-2,3-diol, pentane-2,4-diol, pentane-1,2,3-triol, pentane-1,2,4-triol, pentane-1,2,5-triol, pentane-2,3,4-triol, pentane-1,2,3,4-tetraol, pentane-1,2,3,5-tetraol, pentane-1,2,4,5-tetraol.

In some embodiments, the first precursor comprises an alkoxy group.

In some embodiments, the oxide material layer comprises silicon oxide, and the first precursor comprises an alkoxy silane precursor. In some embodiments, the oxide material layer comprises silicon oxide, and the first precursor is an alkoxy silane precursor. In some embodiments, the alkoxysilane is selected from a group consisting of tetraacetoxysilane, tetramethoxysilane, tetraethoxysilane, trimethoxysilane, triethoxysilane and trimethoxy(3-methoxypropyl)silane.

In some embodiments, the oxide material of the oxide material layer is a metal oxide, and the first precursor is a metal alkoxide. In some embodiments, the oxide material is a metal oxide, and the first precursor comprises a metal alkoxide. In some embodiments, the first precursor comprises a metal atom, an alkyl group and an alkoxide group. In some embodiments, the metal of the metal precursor is a transition metal.

In some embodiments, the metal of the first precursor is selected from a group consisting of Al, Ga and In. In some embodiments, the first precursor is selected from a group consisting of aluminum propoxide (Al(OⁿPr)₃), aluminum isopropoxide (Al(OⁱPr)₃), aluminum sec-butoxide (Al(O^{s}Bu)₃), aluminum ethoxide (Al(OEt)₃), Al(NⁱPr₂)₂(C₃H₆NMe₂), dimethylaluminum isopropoxide (AlMe₂OⁱPr), dimethylgallium isopropoxide (GaMe₂OⁱPr), In(dmamp)₂(OiPr).

In some embodiments, the first precursor comprises a cyclopentadienyl group. In some embodiments, the first precursor comprises a heteroleptic precursor comprising a group 3 metal, at least one cyclopentadienyl ligand and at least one amidinato ligand. In some embodiments, the first precursor is a heteroleptic precursor comprising a group 3 metal, at least one cyclopentadienyl ligand and at least one amidinato ligand. In some embodiments, the oxide material comprises a metal oxide, and the metal of the metal oxide is selected from a group consisting of scandium (Sc), yttrium (Y), lanthanum (La) and cerium (Ce). In some embodiments, the oxide material is a metal oxide, and the metal of the metal oxide is selected from a group consisting of scandium (Sc), yttrium (Y), lanthanum (La) and cerium (Ce). In some embodiments, the metal oxide is a scandium oxide, and the first metal precursor is a scandium precursor. In some embodiments, the metal oxide is an yttrium oxide, and the first metal precursor is an yttrium precursor. In some embodiments, the metal oxide is a lanthanum oxide, and the first metal precursor is a lanthanum precursor. In some embodiments, the metal oxide is a cerium oxide, and the first metal precursor is a cerium precursor.

In some embodiments, the cyclopentadienyl ligand comprises at least one C1 to C5 alkyl substituent. In some embodiments, the alkyl substituent is selected from a group consisting of methyl, ethyl and linear or branched alkyl groups containing three, four or five carbon atoms. In some embodiments, the first metal precursor comprises two ethylcyclopentadienyl ligands.

In some embodiments, the amidinato ligand comprises an acetamidinato ligand. In some embodiments, the acetamidinato ligand is an alkylacetamidinato ligand. In some embodiments, the alkylacetamidinato ligand comprises a dialkylacetamidinato ligand. In some embodiments, the alkylacetamidinato ligand is a dialkylacetamidinato ligand. In some embodiments, the one or two alkyl groups in the acetamidinato ligand are selected from a group consisting of methyl, ethyl, n-propyl, isopropyl, n-butyl, tert-butyl and sec-butyl.

In some embodiments, the first metal precursor is selected from a group consisting of bis(isopropylcyclopentadienyl)(N,N′-diisopropylacetaminidinato)scandium (Sc(iPrCp)2(iPr-AMD)), bis(ethylcyclopentadienyl)(N,N′-diisopropylacetaminidinato)yttrium (Y(EtCp)₂(iPr-AMD), bis(isopropylcyclopentadienyl)(N,N′-diisopropylacetaminidinato)lanthanum (La(iPrCp)₂(iPr-AMD) and bis(isopropylcyclopentadienyl)(N,N′-diisopropylacetaminidinato)cerium (Ce(iPrCp)₂(iPr-AMD).

In some embodiments, the selectivity of deposition of oxide material layer on the first surface relative to the second surface is greater than about 50%.

In some embodiments, the method comprises a cyclic process, and a deposition cycle comprises providing the first precursor and the oxygen precursor into the reaction chamber. In some embodiments, the method is a cyclic process, and a deposition cycle comprises providing the first precursor and the oxygen precursor into the reaction chamber.

In some embodiments, at least two different pressures are used during a deposition cycle. In some embodiments, a first pressure is used during providing the catalyst into the reaction chamber, and a second pressure is used when providing the first precursor into the reaction chamber. In some embodiments, the first pressure is lower than the second pressure. In some embodiments, the first pressure is lower than about 5 Torr. In some embodiments, the second pressure is higher than or equal to about 5 Torr.

In some embodiments, at least one oxygen precursor is provided into the reaction chamber at least partially simultaneously with the first precursor. In some embodiments, the at least one oxygen precursor is provided into the reaction chamber at least partially after providing the first precursor into the reaction chamber. In some embodiments, the first precursor is provided in two or more consecutive pulses during a deposition cycle. In some embodiments, the method further comprises an activation treatment before the oxide material layer deposition, wherein the activation treatment comprises providing a catalyst into the reaction chamber in a vapor phase; and providing an oxygen precursor into the reaction chamber in a vapor phase. In some embodiments, the catalyst and the oxygen precursor are provided into the reaction chamber cyclically.

In some embodiments, the oxide material is deposited in a substantially water-free environment.

In another aspect, a semiconductor processing assembly for selectively depositing an oxide material layer on a substrate is disclosed. The semiconductor processing assembly comprises one or more reaction chambers constructed and arranged to hold the substrate, a precursor injector system constructed and arranged to provide a first precursor and an oxygen precursor into the reaction chamber in a vapor phase. The semiconductor processing assembly further comprises a first precursor source constructed and arranged to contain the first precursor, and an oxygen source constructed and arranged to contain the oxygen precursor. The semiconductor processing assembly is constructed and arranged to provide the first metal precursor and the oxygen precursor via the precursor injector system into the reaction chamber for selectively depositing metal oxide on the substrate.

In some embodiments, the semiconductor processing assembly further comprises one or more passivation sources, and the precursor injector system is constructed and arranged to provide one more passivation agents into the reaction chamber in a vapor phase before providing the first metal precursor into the reaction chamber.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure.

In the drawings

FIG. 1 is a block diagram of exemplary embodiments of a method according to the current disclosure.

FIG. 2 is a schematic drawing of an embodiment of a semiconductor processing assembly according to the current disclosure.

It will be appreciated that elements in the figures are illustrated for simplicity and clarity, and have not necessarily been drawn to scale. The illustrations presented herein are not meant to be actual views of any particular material, structure, or device, but are merely idealized representations that are used to describe embodiments of the disclosure. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, devices and semiconductor processing assemblies provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

The headings provided herein, if any, are for convenience only and do not necessarily affect the scope or meaning of the claimed subject-matter.

Further, in this disclosure, any two numbers of a variable can constitute a workable range of the variable, and any ranges indicated may include or exclude the endpoints. Additionally, any values of variables indicated may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y1-Yₘ, and Z₁-Zₒ, the phrase is intended to refer to a single element selected from X, Y, and Z, a combination of elements selected from the same class (e.g., X₁ and X₂), as well as a combination of elements selected from two or more classes (e.g., Y₁ and Zo).

In one aspect, a method of selectively depositing an oxide material layer on a first surface of a semiconductor substrate relative to the second surface of the substrate is disclosed. The method comprises providing the substrate comprising the first surface and the second surface in a reaction chamber. As used herein, the term “layer” and/or “film” can refer to any continuous or non-continuous material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. In some embodiments, a layer according to the current disclosure is substantially continuous. In some embodiments, a layer according to the current disclosure is continuous.

### Substrate

The deposition method according to the current disclosure comprises providing a substrate in a reaction chamber. The substrate may be any underlying material or materials that can be used to form, or upon which, a structure, a device, a circuit, or a layer can be formed. A substrate can include a bulk material, such as silicon (e.g., single-crystal silicon), other Group IV materials, such as germanium, or other semiconductor materials, such as a Group II-VI or Group III-V semiconductor materials, and can include one or more layers overlying or underlying the bulk material. Further, the substrate can include various features, such as recesses, protrusions, and the like formed within or on at least a portion of a layer of the substrate. For example, a substrate can include bulk semiconductor material and an insulating or dielectric material layer overlying at least a portion of the bulk semiconductor material. Substrate may include nitrides, for example TiN, oxides, insulating materials, dielectric materials, conductive materials, metals, such as such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers. Specifically, the substrate may comprise a partially fabricated semiconductor device.

A substrate according to the current disclosure comprises a first surface and a second surface. The first surface and the second surface have different material properties, allowing for the selective deposition of an oxide material layer on the first surface. For clarity, the first surface and the second surface may be on the same side of the substrate.

In some embodiments, the substrate may be pretreated or cleaned prior to or at the beginning of the selective deposition process. In some embodiments, the substrate may be subjected to a plasma cleaning process prior to or at the beginning of the selective deposition process. In some embodiments, a plasma cleaning process may not include ion bombardment, or may include relatively small amounts of ion bombardment. For example, in some embodiments, the substrate surface may be exposed to plasma, radicals, excited species, and/or atomic species prior to or at the beginning of the selective deposition process. In some embodiments, the substrate surface may be exposed to hydrogen plasma, radicals, or atomic species prior to or at the beginning of the selective deposition process. In some embodiments, the substrate may be subjected to a chemical cleaning process at prior to or at the beginning of the selective deposition process. In some embodiments, a chemical cleaning process may be performed using an alcohol, such as methanol or ethanol. In some embodiments, a chemical cleaning process may be performed using a beta-diketonate, such as hexafluoroacetylacetone (Hhfac). Without limiting the current disclosure to any specific theory, a cleaning process may reduce a surface, such as a metal surface. In some embodiments, a pretreatment or cleaning process may be carried out in the same reaction chamber as a selective deposition process. However, in some embodiments, a pretreatment or cleaning process may be carried out in a separate reaction chamber.

### Reaction Chamber

The method of depositing an oxide material layer according to the current disclosure comprises providing a substrate in a reaction chamber. In other words, a substrate is in a space where the deposition conditions can be controlled. The reaction chamber may be a single wafer reactor. Alternatively, the reaction chamber may be a batch reactor. The reaction chamber can form part of a vapor processing assembly for manufacturing semiconductor devices, such as a semiconductor processing assembly. The semiconductor processing assembly may comprise one or more multi-station processing chambers. The reaction chamber may be part of a cluster tool in which different processes are performed to form an integrated circuit. Various phases of method can be performed within a single reaction chamber, or they can be performed in multiple reaction chambers, such as reaction chambers of a cluster tool, or deposition stations of a multi-station processing chamber.

In some embodiments, the reaction chamber may be a flow-type reactor, such as a cross-flow reactor. In some embodiments, the reaction chamber may be a showerhead reactor. In some embodiments, the reaction chamber may be a hot-wall reactor. In some embodiments, the reaction chamber may be a space-divided reactor. In some embodiments, the reaction chamber may be a single-wafer ALD reactor. In some embodiments, the reaction chamber may be a high-volume manufacturing single-wafer ALD reactor. In some embodiments, the reaction chamber may be a batch reactor for manufacturing multiple substrates simultaneously.

The reaction chamber of the current disclosure can form part of an atomic layer deposition (ALD) assembly. The reaction chamber can form part of a chemical vapor deposition (CVD) assembly. The processing assembly may be an ALD or a CVD processing assembly. In some parts of the deposition process flow, molecular layer deposition (MLD) may be employed. In some embodiments, the method is performed in a single reaction chamber of a cluster tool, but other, preceding or subsequent, manufacturing steps of the structure or device are performed in additional reaction chambers of the same cluster tool. Optionally, a semiconductor processing assembly including the reaction chamber can be provided with a heater to activate the reactions by elevating the temperature of one or more of the substrate and/or the reactants and/or precursors.

### Cyclic Vapor Deposition

When the substrate is provided in the reaction chamber, an oxide material layer is deposited on the first surface of the substrate by a cyclic vapor deposition process. Cyclic deposition in the current disclosure refers to vapor deposition processes in which deposition cycles, typically a plurality of consecutive deposition cycles, are conducted in a process chamber.

In this disclosure, “gas” can include material that is a gas at normal temperature and pressure (NTP), a vaporized solid and/or a vaporized liquid, and can be constituted by a single gas or a mixture of gases, depending on the context. Precursors according to the current disclosure may be provided to the reaction chamber in gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

Generally, in cyclic deposition processes according to the current disclosure, such as atomic layer deposition (ALD) and molecular layer deposition (MLD), during each cycle, a first precursor is introduced to a reaction chamber and is chemisorbed to a substrate surface (e.g., a substrate surface that may include a previously deposited material from a previous deposition cycle or other material). In some embodiments, the first precursor on the substrate surface does not readily react with additional first precursor (i.e., the deposition of the first precursor may be a partially or fully self-limiting reaction). Thereafter, a second precursor or a reactant may be introduced into the reaction chamber for use in converting the chemisorbed first precursor to the desired material on the deposition surface. The second precursor or a reactant can be capable of further reaction with the precursor. Purging steps may be utilized during one or more cycles, e.g., during each step of each cycle, to remove any excess first precursor from the process chamber and/or remove any excess second precursor, reactant and/or reaction byproducts from the reaction chamber. Thus, in some embodiments, the cyclic deposition process comprises purging the reaction chamber after providing a first precursor into the reaction chamber. In some embodiments, the cyclic deposition process comprises purging the reaction chamber after providing an oxygen precursor into the reaction chamber. In some embodiments, the cyclic deposition process comprises purging the reaction chamber after providing a second metal precursor into the reaction chamber. In some embodiments, the cyclic deposition process comprises purging the reaction chamber after providing a first precursor into the reaction chamber, after providing an oxygen precursor into the reaction chamber and after providing a second metal precursor into the reaction chamber. Without limiting the current disclosure to any specific theory, ALD and MLD may be similar processes in terms of self-limiting reactions and slower and more controllable layer growth speed compared to CVD. Generally, ALD is used to deposit inorganic materials, whereas in MLD, the precursors may be fully organic molecules.

In some embodiments, the vapor deposition method according to the current disclosure comprises providing a first precursor and an oxygen precursor into the reaction chamber alternately and sequentially. Such a configuration for providing the two precursors (i.e. first precursor pulse and oxygen precursor pulse, respectively), may be beneficial in view of controlled layer growth, selectivity, layer uniformity and/or conformality. The second metal precursor may be also provided alternately and sequentially relative to the first precursor and/or the oxygen precursor.

In some embodiments, the process according to the current disclosure may contain a CVD component. CVD-type processes may be characterized by vapor deposition which is not self-limiting. They typically involve gas phase reactions between two or more precursors and/or reactants. The precursor(s) and reactant(s) can be provided simultaneously to the reaction space or substrate, or in partially or completely separated pulses. However, CVD may be performed with a single precursor, or two or more precursors that do not react with each other. A single precursor may decompose into reactive components that are deposited on the substrate surface. The decomposition may be brought about by plasma or thermal means, for example. The substrate and/or reaction space can be heated to promote the reaction between the gaseous precursor and/or reactants. In some embodiments the precursor(s) and reactant(s) are provided until a layer having a desired thickness is deposited. In some embodiments, cyclic CVD processes can be used with multiple cycles to deposit a thin film having a desired thickness. In cyclic CVD processes, the precursors and/or reactants may be provided to the reaction chamber in pulses that do not overlap, or that partially or completely overlap. The process may comprise one or more cyclic phases. In some embodiments, the process comprises one or more acyclic (i.e. continuous) phases. An example of a continuous phase is a pre-treatment with a single reactant. In some embodiments, the deposition process comprises the continuous flow of at least one precursor. In some embodiments, one or more of the precursors are provided in the reaction chamber continuously.

In some embodiments, at least one of first precursor, oxygen precursor and second metal precursor is provided into the reaction chamber in pulses. In some embodiments, the first precursor is supplied in pulses and the oxygen precursor is supplied in pulses, and the reaction chamber is purged between consecutive pulses of first precursor and oxygen precursor. In some embodiments, the second metal precursor is supplied in pulses and the oxygen precursor is supplied in pulses, and the reaction chamber is purged between consecutive pulses of second metal precursor and oxygen precursor. In some embodiments, the first precursor is supplied in pulses and the second metal precursor is supplied in pulses, and the reaction chamber is purged between consecutive pulses of first precursor and second metal precursor. A duration of providing first precursor and/or a second metal precursor into the reaction chamber (i.e. first precursor pulse time and second metal precursor pulse time, respectively) may be, for example, from about 0.1 s to about 60 s, for example from about 0.1 s to about 5 s, or from about 1 s to about 20 s, or from about 1 s to about 8 s, or from about 0.5 s to about 10 s, or from about 5 s to about 15 s, or from about 10 s to about 30 s, or from about 10 s to about 60 s, or from about 20 s to about 60 s. The duration of a first precursor or a second metal precursor pulse may be, for example about 0.3 s, 0.5 s, 1 s, 1.5 s, 2 s, 2.5 s, 3 s, 4 s, 5 s, 8 s, 10 s, 12 s, 15 s, 25 s, 30 s, 40 s, 50 s or 60 s. In some embodiments, first precursor or second metal precursor pulse time may be at least 1 second, or at least 3 seconds. In some embodiments, first precursor or second metal precursor pulse time may be at most 2 seconds, or at most 5 seconds or at most 10 seconds, or at most 30 seconds.

A duration of providing oxygen precursor into the reaction chamber (i.e. oxygen precursor pulse time) may be, for example, from about 0.05 s to about 60 s, for example from about 0.05 s to about 5 s, or from about 0.1 s to about 20 s, or from about 0.2 s to about 8 s, or from about 0.5 s to about 10 s, or from about 5 s to about 15 s, or from about 10 s to about 30 s, or from about 20 s to about 60 s. The duration of an oxygen precursor pulse may be, for example about 0.15 s, 0.2 s, 0.3 s, 0.4 s, 0.5 s, 1 s, 1.5 s, 2 s, 2.5 s, 3 s, 5 s, 7 s, 10 s, 12 s, 15 s, 25 s, 30 s, 40 s, 50 s or 60 s. In some embodiments, oxygen precursor pulse time may be at least 0.25 seconds, or at least 0.5 seconds. In some embodiments, oxygen precursor pulse time may be at most 2 seconds, or at most 5 seconds or at most 10 seconds, or at most 30 seconds.

The pulse times for first precursor, for second metal precursor and for oxygen precursor vary independently according to process in question. The selection of an appropriate pulse time may depend on the substrate topology, such as the aspect ratio of features on or in the substrate. For higher aspect ratio structures, longer pulse times may be needed to obtain sufficient surface saturation in different areas of a high aspect ratio structure. Also the selected precursor chemistries may influence suitable pulsing times. For process optimization purposes, shorter pulse times might be preferred as long as appropriate layer properties can be achieved. In some embodiments, first precursor pulse time is longer than second metal precursor pulse time. In some embodiments, second metal precursor pulse time is longer than first precursor pulse time. In some embodiments, first precursor pulse time is the same as second metal precursor pulse time. In some embodiments, first precursor pulse time is longer than oxygen precursor pulse time. In some embodiments, oxygen precursor pulse time is longer than first precursor pulse time. In some embodiments, first precursor pulse time is the same as oxygen precursor pulse time. In some embodiments, second metal precursor pulse time is longer than oxygen precursor pulse time. In some embodiments, oxygen precursor pulse time is longer than second metal precursor pulse time. In some embodiments, second metal precursor pulse time is the same as oxygen precursor pulse time.

In some embodiments, providing first precursor and/or a second metal precursor into the reaction chamber comprises pulsing the first precursor and the second metal precursor over a substrate. In certain embodiments, pulse times in the range of several minutes may be used for the first precursor and/or the second metal precursor. In some embodiments, first precursor may be pulsed more than one time, for example two, three or four times, before a second metal precursor or an oxygen precursor is pulsed to the reaction chamber. Similarly, there may be more than one pulse, such as two, three or four pulses, of a second metal precursor or oxygen precursor before first precursor is pulsed (i.e. provided) into the reaction chamber.

In the methods according to the current disclosure, the vapor deposition process comprises providing a first precursor into the reaction chamber in a vapor phase, providing an oxygen precursor into the reaction chamber in a vapor phase. In some embodiments, a deposition cycle comprises providing a second metal precursor into the reaction chamber. As described above, the process is a cyclic deposition process, so providing (i.e. pulsing) the precursors into the reaction chamber is repeated. The pulses may be repeated as desired, depending on, for example, the growth rate of the oxide material, and on the intended thickness of the oxide material layer. In some embodiments, the growth rate of the oxide material layer is from about 0.01 nm per cycle to about 0.5 nm per cycle. In some embodiments, the growth rate of the oxide material layer is from about 0.01 nm per cycle to about 0.05 nm per cycle, such as about 0.02 nm per cycle or about 0.03 nm per cycle. In some embodiments, the growth rate of the oxide material layer is from about 0.03 nm per cycle to about 0.1 nm per cycle, such as about 0.07 nm per cycle or about 0.08 nm per cycle or about 0.09 nm per cycle. In some embodiments, the growth rate of the oxide material layer is from about 0.05 nm per cycle to about 0.3 nm per cycle, such as about 0.15 nm per cycle or about 0.2 nm per cycle or about 0.25 nm per cycle. In some embodiments, the growth rate of the oxide material layer is from about 0.1 nm per cycle to about 0.5 nm per cycle, such as about 0.35 nm per cycle or about 0.4 nm per cycle or about 0.45 nm per cycle.

The oxide material layer thickness may be selected according to the application in question. In some embodiments, the deposited oxide material layer has a thickness from about 0.03 nm to about 10 nm. Thus, depending on the growth rate of the oxide material layer, the deposition cycle may be performed from about 2 to about 800 times. For example, a deposition cycle may be performed about 2, 3, 5, 7, 10, 13, 15, 20, 40, 50, 100, 200, 300, 500 or 600 times.

In some embodiments, the deposition is performed under reduced pressure. In some embodiments, the oxide material layer according to the current disclosure is deposited at a pressure of at least 0.01 Torr to at most 100 Torr, or at a pressure of at least 0.1 Torr to at most 50 Torr, or at a pressure of at least 0.5 Torr to at most 25 Torr, or at a pressure of at least 1 Torr to at most 10 Torr, or at a pressure of at least 2 Torr to at most 5 Torr. For example, the oxide material layer may be deposited at a pressure of about 1 Torr, about 3 Torr, about 6 Torr, about 8 Torr, about 9 Torr, about 12 Torr or about 18 Torr.

In some embodiments, the deposition according to the current disclosure is performed in a substantially oxygen-free atmosphere. In some embodiments, the deposition is performed under reduced pressure in a substantially oxygen-free atmosphere. Thus, in some embodiments, the oxygen precursor is substantially the only oxygen source for the oxide material deposited according to the current disclosure. For example, the deposition according to the current disclosure may be performed in substantially water-free environment.

The scaling of semiconductor devices, such as, for example, complementary metal-oxide-semiconductor (CMOS) devices, has led to significant improvements in speed and density of integrated circuits. However, conventional device scaling techniques face significant challenges for future technology nodes. For example, one challenge has been finding suitable dielectric stacks that form an insulating barrier between a gate and a channel of a field effect transistor, while keeping the number of processing steps economic and feasible for allowing reliable device manufacture. One particular problem in this regard is the deposition of layers controlling the threshold voltage of field effect transistors. Thus, in one aspect, a threshold voltage shifting layer deposited according to methods disclosed herein is disclosed. Thus, in some embodiments, the oxide material layer is a threshold voltage shifting layer. The term “threshold voltage” as used herein refers to a minimum gate voltage required to create a conductive path between the source and drain terminals of a field effect transistor. The term “threshold voltage shifting layer” as used herein refers to a layer which is useful for controlling the threshold voltage of a metal oxide field effect transistor. Thus, it refers to a layer which can be used in the gate stack of a field effect transistor, and which can change the threshold voltage of that field effect transistor. It may be equivalent to similar terms such as “threshold voltage tuning layer”, “dipole layer”, or “threshold voltage controlling layer”.

In such embodiments, layers of, for example, about 1 nm or less in thickness, may be desired. Correspondingly a deposition cycle may be performed from about 2 times to about 100 or 150 times, such as about 2, 3, 5, 7, 10, 13, 15, 20, 40, 50, 75 or 120 times.

The present methods and devices for selectively depositing a threshold voltage shifting layer are particularly useful for controlling the threshold voltage of n-channel field effect transistors, such as n-channel metal-oxide semiconductor field effect transistors, such as n-channel gate-all-around metal oxide semiconductor field effect transistors. In some embodiments, the present methods and devices are particularly useful for controlling the threshold voltage of p-channel field effect transistors, such as p-channel metal-oxide semiconductor field effect transistors, such as p-channel gate-all-around metal oxide semiconductor field effect transistors. In particular, the present methods and devices are particularly useful for inducing a positive flatband voltage shift for metal oxide semiconductor field effect transistors (MOSFETs). Thus, the present methods and devices are particularly useful for increasing the gate voltage at which a conductive channel is produced between the source and drain of an n-MOSFET. The n-MOSFET may, for example, be comprised in a CMOS-based integrated circuit. Additionally or alternatively, the present methods and devices are particularly useful for decreasing the gate voltage at which a conductive channel is produced between the source and drain of a p-MOSFET. The p-MOSFET may, for example, be comprised in a CMOS-based integrated circuit. In other words, the present methods and devices are particularly useful for increasing the voltage at which an n-MOSFET switches from an off-state to an on-state, and for decreasing the voltage at which a p-MOSFET switches from an off-state to an on-state. Similarly, the present methods and devices are particularly useful for increasing the flat band voltage of n-MOSFETS, and for decreasing the flat band voltage of p-MOSFETS. The present methods and devices are particularly useful for the manufacture of n-MOSFETS and p-MOSFETS with a gate-all-around architecture. Additionally or alternatively, the present methods and devices may be of particular use in the context of systems-on-a-chip. Advantageously, the presently disclosed methods allow depositing threshold shifting layers contributing only minimally to the equivalent oxide thickness of the gate dielectric stack while simultaneously offering a low growth rate and providing a significant positive threshold voltage shift.

The presently disclosed methods may allow depositing threshold voltage shifting layers having a low impurity content, such as a carbon content of less than 2.5 at-% or of less than 2.0%.

The presently described methods and devices are useful for controlling the threshold voltage of field effect transistors. In some embodiments, the present methods and devices are useful for controlling the threshold voltage of n-channel field effect transistors, such as n-channel metal-oxide semiconductor field effect transistors, such as n-channel gate-all-around metal oxide semiconductor field effect transistors. In some embodiments, the present methods and devices are particularly useful for controlling the threshold voltage of p-channel field effect transistors, such as p-channel metal-oxide semiconductor field effect transistors, such as p-channel gate-all-around metal oxide semiconductor field effect transistors. In particular, the present methods and devices are particularly useful for inducing a positive flatband voltage shift for metal oxide semiconductor field effect transistors (MOSFETs). Thus, the present methods and devices are particularly useful for increasing the gate voltage at which a conductive channel is produced between the source and drain of an n-MOSFET. The n-MOSFET may, for example, be comprised in a CMOS-based integrated circuit. Additionally or alternatively, the present methods and devices are particularly useful for decreasing the gate voltage at which a conductive channel is produced between the source and drain of a p-MOSFET. The p-MOSFET may, for example, be comprised in a CMOS-based integrated circuit.

In some embodiments, the oxide material layer is an etch stop layer. The term “etch stop layer”, as used herein, refers to a layer that has a lower etch rate than another material on the same substrate in an etching process used in a process for manufacturing a semiconductor device. An etch stop layer is used to protect an underlying material from etching. In some embodiments, an etch stop layer is substantially note etched under the etching conditions it is used. An etch stop layer may not have the desired properties for the semiconductor device, so it may be removed after the etching is complete. In some cases, for example, when the etch stop layer is sufficiently thin, or does not otherwise adversely affect the semiconductor device, it may remain in the final structure. An etch stop layer may have a thickness of from about 0.5 nm to about 10 nm, such as about 1 nm, about 2 nm, about 3 nm or about 4 nm, about 5 nm or about 7 nm. Correspondingly, to achieve the desired thickness of an etch stop layer, a deposition cycle may be performed from about 2 times to about 500 or about 600 times, such as about 3, 5, 10, 15, 25, 50, 75, 100, 150, 200, 250, 300, 400, 450 or 550 times. As a metal oxide etch stop layer may be very etch resistant, using, for example an yttrium oxide layer may have advantages, as it can be kept very thin, such as under 2 nm or under 1 nm, or under 0.5 nm.

As an example, yttrium oxide (Y₂O₃)-based etch stop layers may be used as hard masks in patterning of structures on semiconductor substrates. Metal oxide, such as yttrium oxide, hard masks demonstrate a much higher etch resistance than carbon-based ones, preventing, for example, the “corner rounding” phenomenon during extended etch processes. By depositing very thin (from about 1 Å to about 10 Å) yttrium oxide layers, the main drawbacks, such as difficulty of removal and effects on device stack performance if not removed, associated with thicker yttrium oxide etch stop layers can be mitigated or omitted. In addition to selective deposition, the yttrium oxide-based hard mask can be used in a non-selective fashion as it can be patterned and removed effectively with chlorine-based wet etch, while it is not etched by HF. Thus, in some embodiments, the etch stop layer described herein may be deposited on a substrate comprising one or more surfaces, substantially without selectivity. In other words, in some embodiments, an etch-stop layer according to the current disclosure may be non-selectively deposited. This may be achieved by selecting a substrate, on which the deposition surfaces are inherently non-selective to the current chemistry, and omitting any passivation disclosed herein.

However, yttrium oxide can also be deposited with excellent selectivity by using heteroleptic precursor comprising yttrium and, at least one cyclopentadienyl ligand and at least one amidinato ligand. Yttrium oxide deposition is selective against surfaces comprising an organic passivation, such as polyimide-comprising passivation. Also, yttrium oxide may be deposited on high k materials, such as on HfO₂ relative to a silylated silicon-containing surface, such as silicon oxide. A selective workflow could eliminate the process steps including the wet-etch to pattern the hard mask, which may be beneficial in many applications. In some embodiments, a substrate comprising a hafnium oxide-comprising first surface may be treated with hydrogen plasma prior to the deposition. In some embodiments, the substrate is treated with hydrogen plasma for about 5 seconds, about 10 seconds, about 20 seconds or about 30 seconds. This may improve the growth rate of the metal oxide on the substrate surface.

An etch stop layer may be removed after the etching process is completed. However, if the etch stop layer is thin enough, there may not be a need to remove it. This may be advantageous in cases where a very resistant etch stop layer is required, and its removal could be challenging. Alternatively or in addition, if the etch stop layer may remain in the completed structure, the process may become simpler, as the removal step for the etch stop layer may be omitted.

Further, the methods and layers according to the current disclosure maybe useful in many other applications, especially in logic, including guiding the deposition of layers, electrical insulation of conductive material and improved via alignment at lower cost.

In some embodiments, the cyclic deposition process according to the current disclosure comprises a thermal deposition process. In thermal deposition, the chemical reactions are promoted by increased temperature relevant to ambient temperature. Generally, temperature increase provides the energy needed for the formation of the target material in the absence of other external energy sources, such as plasma, radicals, or other forms of radiation. In some embodiments, the method according to the current disclosure comprises a plasma-enhanced deposition method, for example PEALD or PECVD. For example, in some embodiments, the oxide material layer deposition may be performed by PEALD or PECVD.

### Selectivity

The current disclosure relates to a selective deposition process. Selectivity can be given as a percentage calculated by [(deposition on first surface)−(deposition on second surface)]/(deposition on first surface). Deposition can be measured in any of a variety of ways. In some embodiments, deposition may be given as the measured thickness of the deposited material. In some embodiments, deposition may be given as the measured amount of material deposited.

In some embodiments, selectivity is greater than about 30%. In some embodiments, selectivity is greater than about 50%. In some embodiments, selectivity is greater than about 75% or greater than about 85%. In some embodiments, selectivity is greater than about 90% or greater than about 93%. In some embodiments, selectivity is greater than about 95% or greater than about 98%. In some embodiments, selectivity is greater than about 99% or even greater than about 99.5%. In embodiments, the selectivity can change over the duration or thickness of a deposition.

In some embodiments, deposition only occurs on the first surface and does not occur on the second surface. In some embodiments, deposition on the first surface of the substrate relative to the second surface of the substrate is at least about 80% selective, which may be selective enough for some particular applications. In some embodiments the deposition on the first surface of the substrate relative to the second surface of the substrate is at least about 50% selective, which may be selective enough for some particular applications. In some embodiments the deposition on the first surface of the substrate relative to the second surface of the substrate is at least about 10% selective, which may be selective enough for some particular applications.

In some embodiments, selective deposition is inherent, and no additional processing steps over those conveniently performed on a substrate are necessary. However, in some embodiments, the second surface may be passivated before depositing an oxide material layer on the first surface. Selectivity may be inherent to a certain thickness of deposited material, and be lost in case deposition is continued beyond a process-specific threshold. Thus, it may be possible to deposit an oxide material layer of, for example, about 0.1 nm, about 0.5 nm, about 1 nm, about 2 nm, about 3 nm, about 5 nm or about 6 nm before selectivity is lost. If thicker material layers are desired, the contrast between the first surface and the second surface may be enhanced though passivating the second surface. Alternatively or in addition, intermittent etch-back phase using, for example plasma, such as hydrogen plasma, may be used to keep the process sufficiently selective. In some embodiments, the second surface comprises passivation. In some embodiments, the passivation comprises a passivation layer on the second surface. In some embodiments, the passivation layer comprises an organic polymer. In some embodiments, the organic polymer comprises polyimide. In some embodiments, the passivation comprises a silylation of the second surface.

In some embodiments, the first surface is a dielectric surface. In some embodiments, the first surface is a low-k surface. By a low k surface is herein meant a surface having at most a similar k value as silicon oxide. In some embodiments, the first surface comprises an oxide. In some embodiments, the first surface comprises a nitride. In some embodiments, the first surface comprises silicon. In some embodiments, the first surface comprises silicon-based dielectric material. Examples of silicon-comprising dielectric materials include silicon oxide-based materials, including grown or deposited silicon dioxide, doped and/or porous oxides and native oxide on silicon. In some embodiments, the first surface comprises silicon oxide. In some embodiments, the first surface is a silicon oxide surface, such as a native oxide surface, a thermal oxide surface or a chemical oxide surface. In some embodiments, the first surface comprises carbon. In some embodiments, the first surface comprises SiN. In some embodiments, the first surface comprises SiOC. In some embodiments, the first surface is an etch-stop layer. An etch-stop layer may comprise, for example a nitride. In some embodiments, the first dielectric surface comprises material selected from a group consisting of SiO₂, SiN, SiC, SiOC, SiON, SiOCN, SiGe and combinations thereof.

In some embodiments, the substrate comprises a first dielectric surface and a second metal or metallic surface. In some embodiments, the substrate comprises a first metal oxide surface. In some embodiments, the first surface may comprise —OH groups. In some embodiments, the first surface may be a SiO₂-based surface. In some embodiments, the first surface may comprise Si—O bonds. In some embodiments, the first surface may comprise a SiO₂-based low-k material. In some embodiments, the first surface may comprise more than about 30%, or more than about 50% of SiO₂. In certain embodiments the first surface may comprise a silicon dioxide surface. Thus, in some embodiments, the first surface comprises silicon. In some embodiments, the first surface is a silicon-comprising dielectric surface.

In some embodiments, the first surface is a SiO₂ surface and the second surface is a metal surface. In some embodiments, the first surface is a SiN surface, and the second surface is a metal surface, such as an elemental metal surface. In some embodiments, the first surface is a SiOC surface, and the second surface is a metal surface. In some embodiments, the first surface is a SiON surface, and the second surface is a metal surface. In some embodiments, the first surface is a SiOCN surface, and the second surface is a metal surface. The second metal surface may be, for example, a copper surface, a ruthenium surface, a tungsten surface, a cobalt surface.

In some embodiments the dielectric material of the first surface comprises a metal oxide. Thus, in some embodiments, an oxide material layer is selectively deposited on a first metal oxide surface relative to a second surface. In some embodiments, the first surface comprises aluminum oxide. In some embodiments, the first surface is a high-k surface, such as hafnium oxide-comprising surface, a lanthanum oxide-comprising surface.

In some embodiments, an oxide material layer is selectively deposited on a first surface comprising a metal oxide relative to another surface. A metal oxide surface may be, for example a tungsten oxide (WOx) surface, hafnium oxide (HfOx) surface, titanium oxide (TiOx) surface, aluminum oxide (AlOx) surface or zirconium oxide (ZrOx) surface. In some embodiments, a metal oxide surface is an oxidized surface of a metallic material. In some embodiments, a metal oxide surface is created by oxidizing at least the surface of a metallic material using one or more oxygen compounds, such as compounds comprising O3, H₂O, H₂O₂, O₂, oxygen atoms, plasma or radicals or mixtures thereof. In some embodiments, a metal oxide surface is a native oxide formed on a metallic material.

In some embodiments, an oxide material layer, is selectively deposited on a first dielectric surface of a substrate relative to a second conductive (e.g., metal or metallic) surface of the substrate. In some embodiments, the first surface comprises hydroxyl (—OH) groups. In some embodiments, the first surface may additionally comprise hydrogen (—H) terminations, such as an HF dipped Si or HF dipped Ge surface. In such embodiments, the surface of interest will be considered to comprise both the —H terminations and the material beneath the —H terminations. In some embodiments the first surface and the second surface are adjacent to each other.

In some embodiments, an oxide material layer is selectively deposited on a first dielectric surface of a substrate relative to a second, different dielectric surface. In some such embodiments, the dielectrics have different compositions. In some embodiments, the first surface comprises a metal oxide. In some embodiments, the metal oxide is selected from aluminum oxide, hafnium oxide and zirconium oxide. In some embodiments, the first surface comprises a high k material. In some embodiments, the high k material is selected from a group consisting of hafnium oxide, zirconium oxide and combinations thereof. In some embodiments, the first surface is a hafnium oxide surface. In some embodiments, the first surface is a zirconium oxide surface. In some embodiments, the first surface is a hafnium zirconium oxide surface. In some embodiments, the first surface is hafnium oxide surface and the second surface is a silicon-containing surface. In some embodiments, the first surface is zirconium oxide surface and the second surface is a silicon-containing surface. In some embodiments, the first surface is hafnium zirconium oxide surface and the second surface is a silicon-containing surface.

In some embodiments, passivation, such as silylation, is used to improve contrast between two dielectric surfaces before depositing an oxide material layer on the first dielectric surface. In some embodiments, the first surface is a high k surface, and the second surface is a passivated low k surface. In some embodiments, the first surface is hafnium oxide surface and the second surface is a silylated silicon-containing surface. In some embodiments, the first surface is zirconium oxide surface and the second surface is a silylated silicon-containing surface. In some embodiments, the first surface is hafnium zirconium oxide surface and the second surface is a silylated silicon-containing surface. The silicon-containing second surface, such as SiO₂, SiN, SiC, SiON or SiOC surface, may be selectively silylated relative to the first surface by a silylating agent. In some embodiments, the silicon-containing second surface is silylated by exposure to a silylation agent, such as an alkylsilane, for example allyltrimethylsilane (TMS-A), halosilane, for example chlorotrimethylsilane (TMS-Cl) or octadecyltrichlorosilane (ODTCS), an imidazole, for example N-(trimethylsilyl)imidazole (TMS-Im), a silazane, for example hexamethyldisilazane (HMDS), or a silylamine, for example N-(trimethylsilyl)dimethylamine (TMSDMA). Silylation may passivate the second surface against the deposition of the oxide material layer on the second surface.

Thus, blocking a dielectric surface may, in some embodiments, allow the selective passivation of another surface, such as a metal surface or a dielectric surface of different composition. In some embodiments, the blocked dielectric surface may be treated, such as with a plasma, to provide the desired surface terminations to facilitate catalyst chemisorption, as described in more detail below.

In some embodiments, the method comprises, before providing the first precursor into the reaction chamber, passivating the first surface with a silylation agent and thereafter depositing an organic polymer on the second surface. For example, the first surface may be a dielectric surface comprising silicon, and the second surface may be a metal or a metallic surface. The first dielectric surface may be passivated with a silylating agent, allowing the second metal or metallic surface to be passivated by an organic polymer-comprising passivation, such as polyimide-comprising passivation layer. The oxide material layer according to the current disclosure may be deposited on the first surface after the initial silylation passivation has been removed. Thus, in some embodiments, the second surface comprises a passivation layer. In some embodiments, the passivation layer comprises polyimide. In some embodiments, the silylation of the dielectric surface aids in the selectivity of the formation of the polymer passivation layer on a second surface. In some embodiments, blocking, such as silylation, does not require a specific removal step before depositing an oxide material on the first surface.

Thus, in some embodiments, the second surface comprises a passivated metal surface. That is, in some embodiments, the second surface may comprise a metal surface comprising a passivation agent. A passivation agent on the second surface may be a polymer layer. In some embodiments, the passivation agent is an organic material, such as an organic polymer. For example, the second organic surface may comprise a polyimide, polyamide, polyuria, polystyrene, polyurethane, polythiourea, polyester, polyimine, polyamic acid, polythiophene or other such polymer. In some embodiments the polymer may include dimers or trimers. In some embodiments the organic surface may comprise other polymeric forms or mixtures of the above materials. For example, an organic passivation layer such as a polyimide-comprising passivation layer or a self-assembled monolayer. In some embodiments, the passivation layer remains on the second surface over at least two, such as at least about 10, about 20, about 50, about 100 or about 150 deposition cycles of the metal oxide. In other words, a passivation layer, such as polyimide-comprising layer, is used that is able to withstand the deposition conditions over an extended period of time.

In some embodiments, an oxide material layer is selectively deposited on a first dielectric surface of a substrate relative to a second metal or metallic surface of the substrate. In some embodiments, the second surface comprises a metal oxide, elemental metal, or metallic surface. In some embodiments, the second metal or metallic surface comprises a passivation layer comprising polyamic acid, polyimide, or other polymeric material.

The term dielectric is used in the description herein for the sake of simplicity in distinguishing from metal or metallic surfaces. It will be understood by those skilled in the art that not all non-conducting surfaces are dielectric surfaces. For example, the metal or metallic surface may comprise an oxidized metal surface that is electrically non-conducting or has a very high resistivity. Selective deposition processes taught herein can deposit on dielectric surfaces with minimal deposition on such adjacent non-conductive metal or metallic surfaces.

For embodiments in which one surface of the substrate comprises a metal, the surface is referred to as a metal surface. In some embodiments, a metal surface consists essentially of, or consists of one or more metals. A metal surface may be a metal surface or a metallic surface. In some embodiments the metal or metallic surface may comprise metal, metal oxides, and/or mixtures thereof. In some embodiments the metal or metallic surface may comprise surface oxidation. In some embodiments the metal or metallic material of the metal or metallic surface is electrically conductive with or without surface oxidation. In some embodiments, metal or a metallic surface comprises one or more transition metals. In some embodiments, the metal or metallic surface comprises one or more transition metals from row 4 of the periodic table of elements. In some embodiments, the metal or metallic surface comprises one or more transition metals from groups 4 to 11 of the periodic table of elements. In some embodiments, a metal or metallic surface comprises aluminum (Al). In some embodiments, a metal or metallic surface comprises copper (Cu). In some embodiments, a metal or metallic surface comprises tungsten (W). In some embodiments, a metal or metallic surface comprises cobalt (Co). In some embodiments, a metal or metallic surface comprises nickel (Ni). In some embodiments, a metal or metallic surface comprises niobium (Nb). In some embodiments, the metal or metallic surface comprises iron (Fe). In some embodiments, the metal or metallic surface comprises molybdenum (Mo). In some embodiments, a metal or metallic surface comprises a metal selected from a group consisting of Al, Mn, Fe, Co, Ni, Cu, Zn, Nb, Mo, Ru and W. In some embodiments, the metal or metallic surface comprises a transition metal selected from a group consisting of Zn, Fe, Mn and Mo.

In some embodiments, a metallic surface comprises titanium nitride. In some embodiments, the metal or metallic surface comprises one or more noble metals, such as Ru. In some embodiments, the metal or metallic surface comprises a conductive metal oxide. In some embodiments, the metal or metallic surface comprises a conductive metal nitride. In some embodiments, the metal or metallic surface comprises a conductive metal carbide. In some embodiments, the metal or metallic surface comprises a conductive metal boride. In some embodiments, the metal or metallic surface comprises a combination of conductive materials. For example, the metal or metallic surface may comprise one or more of ruthenium oxide (RuOx), niobium carbide (NbCx), niobium boride (NbBx), nickel oxide (NiOx), cobalt oxide (CoOx), niobium oxide (NbOx), tungsten carbonitride (WNCx), tantalum nitride (TaN), or titanium nitride (TiN).

In some embodiments, the second surface is a conductive surface. In some embodiments, the second surface comprises a material selected from a group consisting of a metal, amorphous carbon, metal oxide and metal nitride. In some embodiments, the second surface comprises elemental metal. In some embodiments, the metal of the second surface is selected from a group consisting of Cu, Co, Ru, W, Ti, Al, Ta and Mo.

### Catalyst

In some embodiments, particularly in embodiments, in which the first precursor comprises silicon, a metal or metalloid catalyst (“catalyst”) is selectively deposited on the first surface relative to the second surface. In some embodiments, the catalyst is selectively chemisorbed on the first surface, such as a dielectric surface. The catalyst may be, for example, a metal or metalloid catalyst as described below. The term “catalyst” is used throughout the disclosure for simplicity. It is appreciated that in reality, the surface-bound, catalytically active substance may be chemically different from the substance provided into the reaction chamber in vapor phase.

Oxide material is then selectively deposited on the first surface relative to the passivated second surface by providing a silicon precursor into the reaction chamber. The catalyst may improve the interaction between the substrate and the first precursor, such as a silicon precursor, leading to catalytic oxide material growth selectively on the first surface of the substrate relative to the second surface (such as a passivated metal or metal oxide surface). The oxide material may be deposited by a cyclical vapor deposition process in which the substrate is alternately contacted with the catalyst, the first precursor and the oxygen precursor until an oxide material of a desired thickness has been selectively deposited. Following oxide material deposition, the passivation layer on the second surface may be removed, such as by etching. Etching may be performed, for example, by a plasma or a chemical treatment.

In some embodiments, the process according to the current disclosure comprises providing a passivation agent into the reaction chamber in a vapor phase to selectively passivate the second surface before providing a catalyst into the reaction chamber. An organic polymer passivation layer may be selectively formed on the second (for example metal) surface relative to the first dielectric surface by providing a passivation agent into the reaction chamber. A passivation agent may be provided by a cyclic deposition process. For example, polyimide-comprising passivation layer may be deposited by providing an acetic anhydride and a diamine alternately and sequentially into a reaction chamber to form a passivation layer. The passivation layer may be selectively deposited on the second surface by providing a passivating agent into the reaction chamber. In some embodiments, the passivating layer on the metal or metallic surface inhibits, prevents or reduces the formation of the oxide material on the metal or metallic surface.

A plasma treatment may be used to activate the dielectric surface. For example, the silylated dielectric surface may be exposed to a H₂ plasma.

A catalyst is selectively provided on the first surface relative to the second surface, such as by providing a catalyst into the reaction chamber. Therein, the catalyst contacts the substrate. The first surface may be a dielectric surface, and the second surface may be a metal surface. In some embodiments, the substrate is contacted with a catalyst as described below. The catalyst may be, for example, a compound comprising B, Zn, Mg, Mn, La, Hf, Al, Zr, Ti, Sn, Y or Ga. In some embodiments, the catalyst is a metal catalyst. In some embodiments, the catalyst is a metal halide, organometallic or metalorganic compound. In some embodiments, the catalyst may be a metal oxide. In some embodiments, the catalyst is an aluminum catalyst, such as an alkylaluminum catalyst. An aluminum catalyst may comprise trimethyl aluminum (TMA), dimethylaluminumchloride, aluminum trichloride (AlCl₃), dimethylaluminum isopropoxide (DMAI), tris(tertbutyl)aluminum (TTBA), tris(isopropoxide)aluminum (TIPA), tris(dimethylamino)aluminum (TDMAA) or triethyl aluminum (TEA). In some embodiments, the catalyst is a zirconium compound, such as bis(methylcyclopentadienyl)methoxymethyl zirconium (ZrD-04). In some embodiments, the catalyst is tetrakis(ethylmethylamino)zirconium (TEMAZ). In some embodiments, the catalyst is ZrCl₄. In some embodiments, the catalyst is a lanthanum compound, such as tris(isopropyl-cyclopentadienyl)lanthanum (La(iPrCp)₃). In some embodiments, the catalyst is a titanium compound, such as titanium isopropoxide (TTIP) or TiCl₄. In some embodiments, the catalyst is a gallium compound, such as trimethylgallium (TMG). In some embodiments, the catalyst is a hafnium compound, such as HfD-04, HfCl₄ or Hf(NO₃)₄.

In some embodiments, the metal or metalloid catalyst is a metalloid catalyst. In some embodiments, the catalyst comprises an alkylborane. In some embodiments, the catalyst comprises a trialkylborane. In some embodiments, the catalyst comprises a trimethylborane or a triethylborane. A metalloid in the current disclosure means an element selected from a group consisting of boron, silicon, germanium, arsenic, antimony, selenium, antimony and tellurium. In some embodiments, the metalloid element is selected from a group consisting of boron, silicon, germanium, antimony and tellurium. In some embodiments, the metalloid element is selected from a group consisting of boron, silicon, germanium and antimony. In some embodiments, the metalloid element is selected from a group consisting of boron, silicon, germanium and antimony. In some embodiments, the metalloid element is selected from a group consisting of boron, silicon and germanium. In some embodiments, the metalloid element is selected from a group consisting of boron and silicon. In some embodiments, the metalloid element is selected from a group consisting of silicon and germanium. In some embodiments, the metalloid element is silicon.

In some embodiments, the catalyst comprises a compound having the formula MRₓA₃₋ₓ, wherein x is from 1 to 3, R is a C1-C5 alkyl ligand, M is B, Zn, Mg, Mn, La, Hf, Al, Zr, Ti, Sn, Y or Ga and A is a halide, alkylamine, amino, silyl or derivative thereof. In some embodiments, R is a C1-C3 alkyl ligand. In some embodiment R is a methyl or ethyl group. In some embodiments, the M is boron. In some embodiments, the catalyst is ZnRₓA₂₋ₓ, wherein x is from 1 to 2, R is a C1-C5 alkyl ligand, and A is a halide, alkylamine, amino, silyl or derivative thereof. In some such embodiments R is a C1-C3 alkyl ligand. In some embodiment R is a methyl or ethyl group.

In some embodiments, the catalyst may preferentially chemisorb on a dielectric surface, for example on a dielectric surface comprising a blocking agent, relative to a passivated metal surface. In some embodiments, the catalyst preferentially deposits on the dielectric surface relative to the passivated metal surface. In some embodiments, the passivating agent on the metal surface inhibits or prevents deposition of catalyst on the metal surface. In some embodiments, a single exposure to the passivating agent may prevent deposition of catalyst on the metal surface for 1, 2, 5, 10, 20, 30, 40 or 50 or more cycles in which the substrate is contacted with the catalyst. In some embodiments, the second surface is not passivated and the catalyst selectively chemisorbs on the dielectric surface in the absence of a passivating agent on the metal surface. For example, the catalyst may selectively deposit on a dielectric surface comprising a blocking agent relative to a second surface. In some embodiments, a catalyst is not utilized.

After contacting the catalyst with the dielectric surface, oxide material is selectively deposited on the dielectric surface relative to the passivated second surface. For example, the substrate may be exposed to a silicon precursor, such as an alkoxy silane. In some embodiments, the substrate is exposed to the silicon precursor alone, while in some embodiments, the substrate is exposed to the silicon precursor and an oxygen precursor, such as H₂O. The silicon precursor and the oxygen precursor may react with the surface comprising the catalyst to form oxide material. For example, the substrate may be contacted with a silicon precursor comprising an alkoxy silane such that the alkoxy silane decomposes at the catalyst atoms on the dielectric surface, resulting in the selective growth of oxide material on the dielectric surface relative to the second surface.

### Silicon Precursors

The oxide material according to the current disclosure may comprise silicon. For example, oxide material may comprise silicon oxide, or a combination of silicon oxide and a metal oxide. Such materials may comprise silicate. Thus, in some embodiments, the first precursor is a silicon precursor.

As used herein, “silicon precursor” includes a gas or a material that can become gaseous and that can be represented by a chemical formula that includes silicon. In some embodiments, a silicon precursor according to the current disclosure comprises an alkoxy silane. In some embodiments, a silicon precursor is an alkoxy silane. In some embodiments, a silicon precursor does not contain hydroxyl groups. In some embodiments, an alkoxy silane according to the current disclosure comprises four identical alkoxy groups. In some embodiments, an alkoxy silane according to the current disclosure comprises a carboxylate group. In some embodiments, an alkoxy silane according to the current disclosure comprises a silyl ester. In some embodiments, the alkoxysilane is selected from a group consisting of tetraacetoxysilane (tetraacetyl orthosilicate), tetramethoxysilane, tetraethoxysilane (tetraethyl orthosilicate), trimethoxysilane, triethoxysilane and trimethoxy(3-methoxypropyl)silane. In some embodiments, a trialkoxy silane according to the current disclosure comprises a compound of formula RSi(OR′)₃, wherein R is selected from H, 3-aminopropyl, CHCH₃, 3-methoxypropyl, and R′ is selected from CH₃ and CH₂CH₃. In some embodiments, a triethoxy silane according to the current disclosure comprises a compound of formula HSi(OCH₂CH₃)₃. In some embodiments, a triethoxy silane according to the current disclosure comprises triethoxy-3-aminopropyl silane (Si(OCH₂CH₃)₃CH₂CH₂CH₂NH₂). In some embodiments, a triethoxy silane according to the current disclosure comprises triethoxy(ethyl)silane (Si(OCH₂CH₃)₃CHCH₃).

Alkoxy silanes, for example tetraethoxysilane, may have advantages over other silicon precursors in selective deposition applications, as their reactivity is lower. In some embodiments, the silicon precursor does not contain hydroxyl groups. This may apply for OH groups available on the surface of dielectric materials and for metal and metallic surfaces. Alkoxy silanes may also have lower reactivity towards organic passivation agents. In some embodiments, the reduced reactivity towards passivation agents is more pronounced than towards dielectric surfaces. In some embodiments, it is possible to select the process conditions in a way, that growth of oxide material on organic passivation is substantially completely prevented. The reduced reactivity of alkoxy silanes towards organic passivation agents, such as polyimide and/or polyamic acid, may also be more robust than for other silicon precursors, and may be able to tolerate some plasma-induced damage on an organic passivation agent. Taken together, alkoxy silanes in general, and tetraethoxysilane in particular, may have a beneficial selectivity window.

In some embodiments, the silicon precursor is provided two or more times in at least one oxide material deposition subcycle. In some embodiments, the silicon precursor is provided in two or more consecutive pulses during a deposition cycle. In some embodiments, the silicon precursor comprises tetraethoxysilane. In some embodiments, the silicon precursor consists essentially of tetraethoxysilane. In some embodiments, the silicon precursor comprises trimethoxy(3-methoxypropyl)silane. In some embodiments, the silicon precursor consists essentially of trimethoxy(3-methoxypropyl)silane.

### Metal Precursors

The oxide material according to the current disclosure may comprise a metal. For example, oxide material may comprise a metal oxide, or a combination of a metal oxide and silicon oxide. Thus, in some embodiments, the first precursor is a first metal precursor. In some embodiments, metal oxide is a transition metal oxide, and the first precursor is a first transition metal precursor. In some embodiments, the transition metal oxide is a group 4 to group 6 metal oxide, such as titanium oxide, zirconium oxide, hafnium oxide, vanadium oxide, niobium oxide, tantalum oxide, chromium oxide, molybdenum oxide or tungsten oxide. In some embodiments, the metal oxide is a group 13 metal oxide, such as aluminum oxide, indium oxide or gallium oxide.

In some embodiments, the metal precursor is a metal alkoxide. In some embodiments, the oxide material comprises titanium oxide, and the first metal precursor is titanium isopropoxide (Ti(OⁱPr)₄). In some embodiments, the oxide material comprises titanium oxide, and the first metal precursor is titanium tert-butoxide (Ti(O^{t}Bu)₄). In some embodiments, the oxide material comprises titanium oxide, and the first metal precursor is titanium methoxide (Ti(OMet)₄).

In some embodiments, the oxide material comprises niobium oxide, and the first metal precursor is niobium ethoxide (Nb(OEt)₅).

In some embodiments, the oxide material comprises zirconium oxide, and the first metal precursor is zirconium tert-butoxide (Zr(O^{t}Bu)₄). In some embodiments, the oxide material comprises zirconium oxide, and the first metal precursor is zirconium isopropoxide (Zr(OᵢPr)₄). In some embodiments, the oxide material comprises zirconium oxide, and the first metal precursor is Zr (dmae)₂(O^{t}Bu)₂. In some embodiments, the oxide material comprises zirconium oxide, and the first metal precursor is Zr(dmae)₂(OiPr)₂.

In some embodiments, the oxide material comprises hafnium oxide, and the first metal precursor is hafnium tert-butoxide (Hf(O^{t}Bu)₄). In some embodiments, the oxide material comprises hafnium oxide, and the first metal precursor is hafnium isopropoxide (Hf(OⁱPr)₄).

In some embodiments, the oxide material comprises lithium oxide, and the first metal precursor is lithium tert-butoxide (LiO^{t}Bu). In some embodiments, the oxide material comprises vanadium oxide, and the first metal precursor is vanadyl isopropoxide (VO(OⁱPr)₃). In some embodiments, the oxide material comprises tantalum oxide, and the first metal precursor is tantalum ethoxide (Ta(OEt)₅).

In some embodiments, the first metal precursor comprises a s cyclopentadienyl ligand. In some embodiments, the cyclopentadienyl ligand comprises at least one C1 to C5 alkyl substituent. In some embodiments, the alkyl substituent is selected from a group consisting of methyl, ethyl and linear or branched alkyl groups containing three, four or five carbon atoms. In some embodiments, a cyclopentenyl group comprises at least one alkyl substituent, wherein the alkyl substituent is selected from C1 to C5 alkyls. In some embodiments, the alkyl substituent is selected from a group consisting of methyl, ethyl and linear or branched alkyl group comprising three, four or five carbon atoms. In some embodiments, the alkyl substituent is selected from a group consisting of methyl, ethyl, n-propyl, isopropyl, n-butyl, isobutyl, sec-butyl, tert-butyl, n-pentyl, 1,1-dimethylpropyl, 3-methylbutyl, 1-methylbutyl, 2,2-dimethylpropyl, 1-ethylpropyl, 1,2-dimethylpropyl and 2-methylbutyl. In some embodiments, the first metal precursor comprises two methylcyclopentadienyl ligands. In some embodiments, the first metal precursor comprises two ethylcyclopentadienyl ligands. In some embodiments, the first metal precursor comprises two n-propylcyclopentadienyl ligands. In some embodiments, the first metal precursor comprises two isopropylcyclopentadienyl ligands.

In some embodiments, the first metal precursor comprises a s cyclopentadienyl ligand and an amididinato ligand. In some embodiments, the amidinato ligand comprises an acetamidinato ligand. In some embodiments, the acetamidinato ligand is an alkylacetamidinato ligand. In some embodiments, the alkylacetamidinato ligand is a dialkylacetamidinato ligand. In some embodiments, the one or two alkyl groups of the alkylacetamidinato ligand are selected from a group consisting of methyl, ethyl, n-propyl, isopropyl, n-butyl, tert-butyl and sec-butyl. In some embodiments, the acetamidinato group comprises two identical alkyl groups.

The following abbreviations are used in the current disclosure: Me stands for methyl; Et stands for ethyl; Pr stands for propyl; ⁱPr stands for isopropyl; ⁿPr stands for n-propyl; Bu stands for butyl; ^{t}Bu stands for tert-butyl, ^{s}Bu stands for sec-butyl; ^{t}Pn stands for tert-pentyl; Cp stands for cyclopentadienyl; AMD stands for acetamidinato, mmp stands for 1-methoxy-2-methyl-propanolato; acac stands for acetylacetonato; FMD stands for formamidinate; dpguan stands for N,N′-diisopropyl-2-dimethylamidoguanidinato; triaz stands for triazenide; and dmae stands for dimethylaminoethoxide (OCH₂CH₂N(CH₃)₂).

In some embodiments, the oxide material layer comprises scandium, and the first metal precursor is a scandium precursor. In some embodiments, the metal oxide is a scandium oxide, and the first metal precursor is a scandium precursor. In some embodiments, the scandium precursor comprises at least one cyclopentadienyl ligand or an alkyl-substituted variant thereof, and at least one amidinato ligand. In some embodiments, the scandium precursor comprises at least one cyclopentadienyl ligand or an alkyl-substituted variant thereof and at least one alkyl acetamidinato ligand. In some embodiments, the scandium precursor comprises a heteroleptic scandium precursor, such as a precursor comprising at least one alkyl-substituted cyclopentadienyl ligand and at least one alkyl acetamidinato ligand. In some embodiments, the scandium precursor is bis(isopropylcyclopentadienyl)(N,N′-diisopropylacetaminidinato)scandium (Sc(iPrCp)2(iPr-AMD)).

The oxidation state of the metal in the first metal precursor may be higher than 0. The oxidation state of the metal in the first metal precursor may be 3.

In some embodiments, the oxide material layer comprises yttrium, and the first metal precursor is an yttrium precursor. In some embodiments, the metal oxide is an yttrium oxide, and the first metal precursor is an yttrium precursor. In some embodiments, the yttrium precursor comprises at least one cyclopentadienyl ligand or an alkyl-substituted variant thereof and at least one amidinato ligand. In some embodiments, the yttrium precursor comprises at least one cyclopentadienyl ligand or an alkyl-substituted variant thereof and at least one alkyl acetamidinato ligand. In some embodiments, the yttrium precursor comprises at least one cyclopentadienyl ligand or an alkyl-substituted variant thereof and at least one amidinato ligand. In some embodiments, the yttrium precursor comprises a heteroleptic yttrium precursor, such as a precursor comprising at least one alkyl-substituted cyclopentadienyl ligand and at least one alkyl acetamidinato ligand. In some embodiments, the yttrium precursor is bis(ethylcyclopentadienyl)(N,N′-diisopropylacetaminidinato)yttrium (Y(EtCp)₂(iPr-AMD)).

In some embodiments, the oxide material layer comprises lanthanum, and the first metal precursor is a lanthanum precursor. In some embodiments, the metal oxide is a lanthanum oxide, and the first metal precursor is a lanthanum precursor. In some embodiments, the lanthanum precursor comprises at least one cyclopentadienyl ligand or an alkyl-substituted variant thereof. In some embodiments, the lanthanum precursor comprises at least one amidinato ligand. In some embodiments, the lanthanum precursor comprises at least one cyclopentadienyl ligand or an alkyl-substituted variant thereof and at least one alkyl acetamidinato ligand. In some embodiments, the lanthanum precursor comprises a heteroleptic lanthanum precursor, such as a precursor comprising at least one alkyl-substituted cyclopentadienyl ligand and at least one alkyl acetamidinato ligand. In some embodiments, the lanthanum precursor comprises bis(isopropylcyclopentadienyl)(N,N′-diisopropylacetaminidinato)lanthanum (La(iPrCp)₂(iPr-AMD).

In some embodiments, the oxide material layer comprises cerium, and the first metal precursor is a cerium precursor. In some embodiments, the metal oxide is a cerium oxide, and the first metal precursor is a cerium precursor. In some embodiments, the cerium precursor comprises at least one cyclopentadienyl ligand or an alkyl-substituted variant thereof. In some embodiments, the cerium precursor comprises at least one amidinato ligand. In some embodiments, the cerium precursor comprises at least one cyclopentadienyl ligand or an alkyl-substituted variant thereof and at least one alkyl acetamidinato ligand. In some embodiments, the cerium precursor comprises a heteroleptic cerium precursor, such as a precursor comprising at least one alkyl-substituted cyclopentadienyl ligand and at least one alkyl acetamidinato ligand. In some embodiments, the cerium precursor comprises bis(isopropylcyclopentadienyl)(N,N′-diisopropylacetaminidinato)cerium (Ce(iPrCp)₂(iPr-AMD).

In some embodiments, the first metal precursor according to the current disclosure may be presented by the formula M(RCp)ₓ[R′N(CR″)NR′″]_{y}, wherein M is selected from Sc, Y, La, Ce and other rare earth elements, R is H, Me, Et, ⁱPr, ^{t}Bu, R′ is Et, ⁱPr, ^{t}Bu, ^{t}Pn, R″ is H, Me, Et, Pr, Bu, R′″ is Et, ⁱPr, ^{t}Bu, ^{t}Pn and x+y=3, wherein x and y are both integers greater than zero. This example would be for compounds comprising both Cp and amidinate type ligands.

In some embodiments, the oxide material comprises zirconium oxide, and the first metal precursor is a zirconium precursor comprising a Cp ligand. In some embodiments, the zirconium precursor is selected from a group consisting of Zr(Cp)(^{t}BuDAD)(OⁱPr), Zr(Cp₂CMe₂)Me(OMe), Zr(Cp₂CMe₂)Me₂, Zr(CpEt)(NMe₂)₃, Zr(CpMe)(NMe₂)₃, Zr(CpMe)₂Me(OMe), Zr(CpMe)₂Me₂, Zr(CpMe)CHT, Zr(CpMe₂)₂Me(O^{t}Bu), Zr(Me₅Cp)(TEA), Zr(MeCp)(TMEA), ZrCp₂Cl₂, and ZrCp₂Me(OMe).

In some embodiments, the oxide material comprises zirconium oxide, and the first metal precursor is a zirconium precursor comprising a Cp ligand. In some embodiments, the zirconium precursor is selected from a group consisting of Hf(Cp)(NMe₂)₃, Hf(Cp₂CMe₂)Me(OMe), Hf(Cp₂CMe₂)Me₂, Hf(CpMe)(NMe₂)₃, Hf(CpMe)₂(mmp)Me, Hf(CpMe)₂(OⁱPr)Me, Hf(CpMe)₂(OMe)Me, Hf(CpMe)₂Me₂, HfCp(edpa)₃, HfCp₂Cl₂ and HfCp₂Me₂.

In some embodiments, a second metal precursor is provided into the reaction chamber. The second metal precursor may contain the same metal as the first metal precursor or a different metal. Thus, a second element can be introduced into the deposited material. In some embodiments, the first precursor is a first metal precursor, and the second metal precursors comprises a metal that is different from the first metal. In embodiments, in which the second metal precursor comprises a different metal than the first metal precursor, the oxide material layer comprises two metals. In some embodiments, the first precursor is a first metal precursor, and the second metal precursor comprises the same metal as the first metal precursor. In some embodiments, the first precursor is a silicon precursor, and the second metal precursor comprises a meta, and oxide material comprising both silicon and metal is deposited. The molar ratio of the first metal or silicon to second metal in an oxide material layer comprising two metals may vary from 1:50 to 50:1. In the most extreme embodiments, the oxide material layer comprises mostly the first metal, silicon or the second metal, and the other one is used as a dopant. In some embodiments, the molar ratio of the first metal or silicon to second metal in an oxide material layer comprising two metals varies from about 1:20 to about 20:1 or from about 1:10 to about 10:1 or from about 1:5 to about 5:1. In some embodiments, the molar ratio of the first metal or silicon to second metal in an oxide material layer comprising two metals varies from about 1:3 to about 3:1 or from about 1:2 to about 2:1. In some embodiments, the molar ratio of the first metal or silicon to second metal in an oxide material layer comprising two metals is about 1:2, about 2:1, about 3:2, about 2:3 or about 1:1.

In some embodiments, the second metal is a transition metal, and the second metal precursor is a transition metal precursor. In some embodiments, the second metal is a post-transition metal, and the second metal precursor is a post-transition metal precursor. In some embodiments, the second metal is a group 13 metal, and the second metal precursor is a group 13 metal precursor. In some embodiments, the group 13 metal is selected from a group consisting of aluminum, gallium and indium. In some embodiments, the group 13 metal is aluminum, and the second metal precursor is an aluminum precursor. In some embodiments, the group 13 metal is gallium, and the second metal precursor is a gallium precursor. In some embodiments, the group 13 metal is indium, and the second metal precursor is an indium precursor. Examples of aluminum precursors include but are not limited to AlMe₃, AlEt₃, Al(OEt)₃, Al(OⁿPr)₃, Al(OⁱPr)₃, Al(O^{s}Bu)₃, Al(ⁱPrAMD)Et₂, Al(mmp)₃, Al(NMe₂)₃, Al(NEt₂)₃, AlCl₃, AlMe₂Cl, AlMe₂OⁱPr, Al(NⁱPr₂)₃ and Al(NⁱPr₂)₂(C₃H₆NMe₂). Examples of gallium precursors include but are not limited to Ga(acac)₃, Ga(CpMe₅), Ga₂(NMe₂)₆ and GaMe₂(OⁱPr). Examples of indium precursors include but are not limited to In(acac)₃, In(dpguan)₃, In(EtCp), In(ⁱPrAMD)₃, In(ⁱPrFMD)₃, In(N(SiMe₃)₂)Et₂, In(PrNMe₂)Me₂, In(triaz)₃, InCl₃, InCp, InMe₂(edpa), InMe₃, InMe₃(MeO(CH₂)₂NH^{t}Bu).

### Oxygen Precursor

The methods according to the current disclosure comprise providing an oxygen precursor into the reaction chamber to selectively deposit oxide material on the substrate. The oxygen precursor according to the current disclosure comprises a hydroxyl group. In some embodiments, a one or more hydroxyl groups is substantially the only reactive group in the oxygen precursor. In some embodiments, the oxygen precursor is an alcohol. In some embodiments, the alcohol is substantially the only oxygen source in the deposition process.

In some embodiments, the alcohol is a primary alcohol. In some embodiments, the alcohol is a secondary alcohol. In some embodiments, the alcohol is a tertiary alcohol. In some embodiments, the oxygen precursor is a secondary or tertiary alcohol. In some embodiments, the alcohol comprises one carbon atom. In some embodiments, the alcohol comprises two carbon atoms. In some embodiments, the alcohol comprises three carbon atoms. In some embodiments, the alcohol comprises four carbon atoms. In some embodiments, the alcohol comprises five carbon atoms. In some embodiments, the alcohol comprises six carbon atoms.

In some embodiments, the alcohol comprises one hydroxyl group. In some embodiments, the alcohol comprises two hydroxyl groups. In some embodiments, the alcohol comprises at least two hydroxyl groups. In some embodiments, the alcohol comprises three hydroxyl groups. In some embodiments, the alcohol comprises at least three hydroxyl groups. In some embodiments, the alcohol comprises four hydroxyl groups. In some embodiments, the alcohol comprises at least four hydroxyl groups. In some embodiments, the alcohol comprises five hydroxyl groups. In some embodiments, the alcohol comprises at least five hydroxyl groups.

In some embodiments in which the oxygen precursor comprises at least two hydroxyl groups, each hydroxyl group is bonded to a different carbon atom. In some embodiments, two hydroxyl groups are bonded to one carbon atom. In some embodiments, at least two hydroxyl groups are bonded to one carbon atom. In some embodiments, the alcohol comprises two carbon atoms being bonded to two hydroxyl groups. In some embodiments, the alcohol comprises at least two carbon atoms being bonded to two hydroxyl groups. In some embodiments, the alcohol comprises three carbon atoms being bonded to two hydroxyl groups. In some embodiments, the alcohol comprises at least three carbon atoms being bonded to two hydroxyl groups. In some embodiments, the oxygen precursor does not comprise carboxyl groups. In some embodiments, the only oxygen atom(s) in the oxygen precursor are in the hydroxyl groups. In some embodiments, the oxygen precursor contains only carbon and hydrogen in addition to the oxygen in the hydroxyl group(s). In some embodiments, an additional oxygen precursor may be used for tuning the deposition process. For example, a high-reactivity oxygen precursor, such as ozone, or oxygen plasma, may be used at the end of the process to ascertain sufficient conversion of the first precursor and the optional second metal precursor into oxide material.

In some embodiments, the oxygen precursor is selected from a group consisting of methanol, ethanol, propan-1-ol, propan-2-ol, butan-1-ol, butan-2-ol, pentan-1-ol, iso-butanol, tert-butanol, pentan-2-ol, pentan-3-ol, ethane-1,2-diol, propane-1,2-diol, propane-1,2,3-triol, butane-1,2-diol, butane-2,3-diol, butane-1,3-diol, butane-1,4-diol, butane-1,2,3-triol, butane-1,2,3,4-tetraol, pentane-1,2-diol, pentane-1,3-diol, pentane-1,4-diol, pentane-1,5-diol, pentane-2,3-diol, pentane-2,4-diol, pentane-1,2,3-triol, pentane-1,2,4-triol, pentane-1,2,5-triol, pentane-2,3,4-triol, pentane-1,2,3,4-tetraol, pentane-1,2,3,5-tetraol, pentane-1,2,4,5-tetraol.

In accordance with some exemplary embodiments, a structure is formed using methods as described herein. The structure can include a substrate and an oxide material layer, such as a threshold voltage shifting layer or an etch stop layer, formed overlying a surface of the substrate. Exemplary structures can further include one or more additional layers, such as an additional metal or conducting layer overlying the oxide material layers and/or one or more insulating or dielectric layers underneath the oxide material layer. The structure can be or form part of a CMOS structure, such as one or more of a PMOS and NMOS structure, or other device structure.

In accordance with yet additional embodiments of the disclosure, a device or portion thereof can be formed using methods and/or structures as described herein. The device can be or form part of, for example, a CMOS device.

### DRAWINGS

The disclosure is further explained by the following exemplary embodiments depicted in the drawings. The illustrations presented herein are not meant to be actual views of any particular material, structure, or assembly, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures, devices and assemblies depicted in the drawings may contain additional elements and details, which may be omitted for clarity.

For the sake of brevity, conventional manufacturing, connection, preparation, and other functional aspects of the methods and assemblies described herein may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

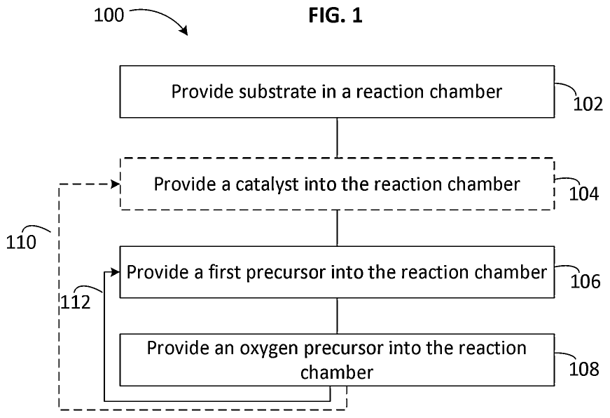

FIG. 1 is a block diagram of exemplary embodiments of a method 100 according to the current disclosure. First, a substrate is provided in a reaction chamber at block 102. The substrate comprises a first surface and a second surface as described in the current disclosure. For example, the first surface may be a dielectric surface comprising a passivation blocking agent, such as a silylating agent, and the second surface may be a metal surface, such as copper surface, comprising an organic passivation layer. In an exemplary embodiment, the metal passivation layer comprises polyimide. The deposition of a passivation layer may comprise etching back the deposited passivation layer for improving the accuracy of subsequent selective deposition. The substrate may be heated at block 102 prior to providing a catalyst into the reaction chamber.

After providing the substrate into the reaction chamber, 102, a catalyst is optionally provided into the reaction chamber at block 104 to contact the catalyst with the substrate. The catalyst may be, for example, an aluminum-comprising catalyst, such as dimethylaluminum isopropoxide. The catalyst is provided into the reaction chamber in vapor phase. The duration of providing the catalyst may be, for example from about 0.5 seconds to about 10 seconds, such as about 1 second, about 2 seconds, about 3 seconds, about 5 seconds or about 7 seconds. The reaction chamber may be purged after providing the catalyst into the reaction chamber. Purging is not indicated in FIG. 1, but it may be optionally included after block 104. The catalyst may be a metalloid catalyst. For example, the catalyst may comprise boron and/or silicon. In some embodiments, the catalyst is a is a metal catalyst, and may comprise a metal halide, an organometallic compound and/or a metalorganic compound. In some embodiments, the catalyst is a compound comprising at least one element selected from B, Zn, Mg, Mn, La, Hf, Al, Zr, Ti, Sn, Y and Ga. In some embodiments, the catalyst is trimethyl aluminum (TMA), dimethylaluminumchloride, aluminum trichloride (AlCl₃), dimethylaluminum isopropoxide (DMAI), tris(tertbutyl)aluminum (TTBA), tris(isopropoxide)aluminum (TIPA), tris(dimethylamino)aluminum (TDMAA) or triethyl aluminum (TEA).

In some embodiments, the process according to the current disclosure comprises passivation of the second surface before providing the catalyst, or the first precursor, as the case may be, into the reaction chamber. In such embodiments, the passivation may be deposited in the same processing chamber or in a different processing chamber than the deposition of the oxide material. Thus, the passivation may take place already before block 102, or after it.

At block 106, a first precursor is provided into the reaction chamber in a vapor phase. In exemplary embodiments, the first precursor is a silicon precursor, such as tetraethoxysilane. Alternatively, the first precursor may be a first metal precursor, such as aluminum precursor, yttrium precursor or a scandium precursor as disclosed herein. Examples of tested first metal precursors are dimethylaluminum isopropoxide for depositing aluminum oxide material, and bis(ethylcyclopentadienyl)(N,N′-diisopropylacetaminidinato)yttrium for depositing yttrium oxide material. Particularly, a catalyst may be used when a silicon precursor is used, and the oxide material comprises silicon oxide. Thus, in some embodiments, a catalyst is used. For example, selective deposition of aluminum oxide, yttrium oxide and several other metal oxides may not need a catalyst for deposition.

In some embodiments, the oxide material layer comprises silicon oxide, and the first precursor is an alkoxy silane precursor. In some embodiments, the alkoxysilane is selected from a group consisting of tetraacetoxysilane, tetramethoxysilane, tetraethoxysilane, trimethoxysilane, triethoxysilane and trimethoxy(3-methoxypropyl)silane.

In some embodiments, the oxide material is a metal oxide, and the first precursor comprises a metal alkoxide. In some embodiments, the first precursor comprises a metal atom, an alkyl group and an alkoxide group. In some embodiments, the metal of the metal precursor is a transition metal.

In some embodiments, the metal of the first precursor is selected from a group consisting of Al, Ga and In. In some embodiments, the first precursor is selected from a group consisting of aluminum propoxide (Al(OⁿPr)₃), aluminum isopropoxide (Al(OⁱPr)₃), aluminum sec-butoxide (Al(O^{s}Bu)₃), aluminum ethoxide (Al(OEt)₃), Al(NⁱPr₂)₂(C₃H₆NMe₂), dimethylaluminum isopropoxide (AlMe₂OⁱPr), dimethylgallium isopropoxide (GaMe₂OⁱPr), In(dmamp)₂(OiPr).

In some embodiments, the first precursor comprises a cyclopentadienyl group. In some embodiments, the first precursor is a heteroleptic precursor comprising a group 3 metal, at least one cyclopentadienyl ligand and at least one amidinato ligand. In some embodiments, the oxide material is a metal oxide, and the metal of the metal oxide is selected from a group consisting of scandium (Sc), yttrium (Y), lanthanum (La) and cerium (Ce). In some embodiments, the metal oxide is a scandium oxide, and the first metal precursor is a scandium precursor. In some embodiments, the metal oxide is an yttrium oxide, and the first metal precursor is an yttrium precursor. In some embodiments, the metal oxide is a lanthanum oxide, and the first metal precursor is a lanthanum precursor. In some embodiments, the metal oxide is a cerium oxide, and the first metal precursor is a cerium precursor.

In some embodiments, the cyclopentadienyl ligand comprises at least one C1 to C5 alkyl substituent. In some embodiments, the alkyl substituent is selected from a group consisting of methyl, ethyl and linear or branched alkyl groups containing three, four or five carbon atoms. In n some embodiments, the first metal precursor comprises two ethylcyclopentadienyl ligands.

In some embodiments, the amidinato ligand comprises an acetamidinato ligand. In some embodiments, the acetamidinato ligand is an alkylacetamidinato ligand. In some embodiments, the alkylacetamidinato ligand is a dialkylacetamidinato ligand. In some embodiments, the one or two alkyl groups in the acetamidinato ligand are selected from a group consisting of methyl, ethyl, n-propyl, isopropyl, n-butyl, tert-butyl and sec-butyl.

In some embodiments, the first metal precursor is selected from a group consisting of bis(isopropylcyclopentadienyl)(N,N′-diisopropylacetaminidinato)scandium (Sc(iPrCp)2(iPr-AMD)), bis(ethylcyclopentadienyl)(N,N′-diisopropylacetaminidinato)yttrium (Y(EtCp)₂(iPr-AMD), bis(isopropylcyclopentadienyl)(N,N′-diisopropylacetaminidinato)lanthanum (La(iPrCp)₂(iPr-AMD) and bis(isopropylcyclopentadienyl)(N,N′-diisopropylacetaminidinato)cerium (Ce(iPrCp)₂(iPr-AMD).

The first precursor is selectively chemisorbed on the first surface relative to the second surface of the substrate. The first precursor may be provided into the reaction chamber (i.e. pulsed) for about 0.2 to 8 seconds, for example, about 0.5 seconds, about 1 second, about 3 seconds or about 5 seconds. In some embodiments, the first precursor is provided into the reaction chamber in multiple, such as 2, 4 or 10, consecutive pulses. In some embodiments, the first precursor is provided into the reaction chamber in a single pulse for each deposition cycle. The selective chemisorption of the first precursor on the first surface of the substrate may allow the selective deposition of the process according to the current disclosure. The degree of selectivity in the deposition of oxide material layer on the first surface relative to the second surface varies depending on the exact chemistries and deposition conditions. However, in some embodiments, selectivity is greater than about 50%, or greater than about 80%, or greater than about 95%. In some embodiments, selectivity may be observed as a delayed layer growth on the second surface relative to the first surface.

The reaction chamber may be purged after a first precursor pulse. Purging is not indicated in FIG. 1, but it may be optionally included in block 106.

At block 108, an oxygen precursor is provided into the reaction chamber in a vapor phase. In an exemplary embodiment, the oxygen precursor is tert-butanol. In another exemplary embodiment, the oxygen precursor is isopropyl alcohol. However, additional alcohols comprising from 1 to 6 carbon atoms may be utilized. The oxygen precursor may be a secondary or tertiary alcohol. The oxygen precursor reacts with the chemisorbed first precursor to form oxide material on the first surface of the substrate. The oxide material may comprise, for example, silicon oxide, and/or metal silicates, such as aluminum silicate. The reaction chamber may be purged after an oxygen precursor pulse. Purging is not indicated in FIG. 1, but it may be optionally included in block 108.

In some embodiments, the oxygen precursor is selected from methanol, ethanol, propan-1-ol, propan-2-ol, butan-1-ol, butan-2-ol, pentan-1-ol, iso-butanol, tert-butanol, pentan-2-ol, pentan-3-ol, ethane-1,2-diol, propane-1,2-diol, propane-1,2,3-triol, butane-1,2-diol, butane-2,3-diol, butane-1,3-diol, butane-1,4-diol, butane-1,2,3-triol, butane-1,2,3,4-tetraol, pentane-1,2-diol, pentane-1,3-diol, pentane-1,4-diol, pentane-1,5-diol, pentane-2,3-diol, pentane-2,4-diol, pentane-1,2,3-triol, pentane-1,2,4-triol, pentane-1,2,5-triol, pentane-2,3,4-triol, pentane-1,2,3,4-tetraol, pentane-1,2,3,5-tetraol, pentane-1,2,4,5-tetraol.

The deposition process according to the current disclosure may be a cyclic deposition process. In some embodiments, the method is a cyclic process, and a deposition cycle comprises providing the first precursor and the oxygen precursor into the reaction chamber. However, in some embodiments, in which a very thin oxide material layer is needed, performing the process steps only once may be sufficient. Thus, at loop 110 or 112, the deposition cycle is initiated again. If an embodiment comprising loop 110 is used, a catalyst is provided into the reaction chamber at every cycle, and the deposition process may be considered an ABC-process, one deposition cycle comprising three phases. However, cyclic deposition, especially deposition of metal oxide material, may be performed using loop 112. In such embodiments, catalyst at block 104 is not provided into the reaction chamber, or not provided every deposition cycle. In some embodiments, block 104 is not used at all, whereas in other embodiments, block 104 is used only in the beginning of the deposition process. In some further embodiments, block 104 is included every n:th deposition cycle, i.e. the process comprises repeating blocks 106 and 108 through loop 112 for a predetermined number of times (n), after which catalyst is provided into the reaction chamber 104.

To generalize, a deposition process according to the current disclosure may be represented by a formula x[A+n(B+C)], wherein A indicates providing a catalyst into the reaction chamber, B providing a first precursor into the reaction chamber and C providing an oxygen precursor into the reaction chamber. In the formula, x presents the total number of master cycles in the deposition process, and can vary between 1 and about 100, n presents the number of deposition subcycles in which the oxide material is deposited using first precursor and oxygen precursor, and n can vary between 1 and about 100.

Thus, the deposition cycle may be repeated as many times as needed to deposit a desired amount of oxide material on the substrate. For example, the deposition cycle may be performed from 1 to about 1,000 times, or from about 10 to about 500 times, or from about 50 to 300 times. For example, the deposition cycle may be performed about 10 times, about 20 times, about 30 times, about 50 times, about 70 times, about 100 times, about 150 times, about 200 times or about 400 times. Although not depicted in the current disclosure, the process may comprise additional steps, for example refreshing any blocking or passivation that may be necessary for the continued selective deposition. Particularly, the reaction chamber may be purged after any of blocks 104, 106 and 108. In some embodiments, the reaction chamber is purged after each of blocks 104, 106 and 108.

Although not depicted in FIG. 1, oxygen precursor may be provided into the reaction chamber additionally after block 104. If catalyst is, for example, a metal catalyst, such as an aluminum-containing catalyst, a separate subcycle of depositing metal oxide may be formed by alternating providing a catalyst and an oxygen precursor into the reaction chamber. Such an additional subcycle may be repeated, and used to modulate the proportions of different elements in the oxide material.

As indicated above, selective deposition according to the current disclosure may have a broader selectivity window (i.e. selectivity may be observed under a broader range of conditions) relative to methods known in the art. For example, the temperature during the process may vary. In some embodiments, the deposition (including providing a catalyst into the reaction chamber) is performed at a temperature from about 150° C. to about 450° C., such as at 300° C. or at 350° C. In some embodiments, at least two different pressures are used during a deposition cycle. For example, a first pressure is used during providing the catalyst into the reaction chamber, and a second pressure is used when providing the first precursor into the reaction chamber. In some embodiments, the first pressure is lower than the second pressure. In some embodiments, the first pressure is lower than about 5 Torr. In some embodiments, the second pressure is higher than or equal to about 5 Torr.

To avoid oxidative damage to substrate surfaces, and to ascertain a desired degree of selectivity, the oxide material may be deposited in a substantially water-free environment.

In some embodiments, the selective deposition of oxide material on the first surface does not damage an organic passivation layer present on the second surface. Further, in some embodiments, the oxide material is substantially not deposited on an organic passivation layer. Further, using an alcohol as an oxygen precursor may have the benefit of avoiding oxidation of metal surfaces of the substrate. Additionally, the rate of deposition when using an alcohol as an oxygen precursor may be lower compared to conventional, and more oxidizing, oxygen precursors. This may be beneficial in some applications, in which very careful control of oxide material layer thickness, or very thin oxide material layer is targeted. Further, the different deposition schemes presented in FIG. 1 allow for adjusting the composition of the deposited oxide material according to the needs of an application in question.

Although not depicted in FIG. 1, it is possible for the phases of the deposition process to overlap. For example, phases 104 bad 106 may be performed at least partially simultaneously. In some embodiments, phases 106 and 108 are performed at least partially simultaneously. Thus, the different precursors and reactants may be provided into the reaction chamber in various schemes. For example, an oxygen precursor may be provided into the reaction chamber at least partially simultaneously with the first precursor, or an oxygen precursor may be provided into the reaction chamber at least partially after providing the first precursor into the reaction chamber. In some embodiments, the first precursor is provided in two or more consecutive pulses during a deposition cycle.

The selective deposition according to the current disclosure may further comprise providing a second metal precursor into the reaction chamber. The second metal precursor may be provided into the reaction chamber after the first precursor or after the oxygen precursor in a deposition cycle. A deposition cycle may comprise one oxygen pulse (i.e. oxygen precursor is pulsed after providing both first precursor and second metal precursor into the reaction chamber) or two oxygen pulses (i.e., oxygen precursor is pulsed after first precursor pulse and after a second metal precursor pulse). In embodiments, in which a catalyst is used, the catalyst may be provided before a first precursor, before the second metal precursor, or before each. However, in most embodiments, a catalyst is provided into the reaction chamber less frequently than the precursors.

In some embodiments, the first or second metal precursor is not a metal alkyl. Particularly, in some embodiments, the first or second metal precursor is not diethyl zinc. In some embodiments, the first or second metal precursor is not trimethyl indium.

In some tested embodiments, yttrium oxide material was selectively deposited on dielectric surface, such as deposited silicon oxide surface, native silicon surface and thermal silicon oxide surface, relative to a metal or a metallic surface passivated by polyimide. Bis(ethylcyclopentadienyl)(N,N′-diisopropylacetaminidinato)yttrium was used as a first metal precursor, and tert-butanol as an oxygen precursor. The deposition was performed at a temperature of about 350° C. and the growth rate of the material on the dielectric surface was observed to be between 0.5 and 0.8 Å/cycle. In another experiment with the same yttrium precursor and deposition temperature, propan-2-ol was used as an oxygen precursor with similar results, although the growth rate of the oxide material was slightly lower.

In additional tests, aluminum oxide material was selectively deposited on dielectric surface, such as deposited silicon oxide surface, native silicon surface and thermal silicon oxide surface, relative to a passivated metal surface by using dimethyl aluminum isopropoxide as a first metal precursor, and tert-butanol as an oxygen precursor. The deposition was performed at a temperature of about 350° C. and the growth rate of the material on the silicon oxide surface was observed to be from about 0.6 to about 0.8 Å/cycle. In a yet further experiment, with the same aluminum precursor and deposition temperature, propan-2-ol was used as an oxygen precursor with similar results, although the growth rate of the oxide material was slightly lower (0.46 Å/cycle).

For testing the deposition of metal and silicon oxide-comprising material, a process comprising providing dimethyl aluminum isopropoxide and an alkoxy silane into the reaction chamber in addition to the oxygen precursor was performed. The aluminum, silicon and oxygen-comprising material was selectively deposited on a dielectric surface relative to a metal surface under similar conditions as described above.

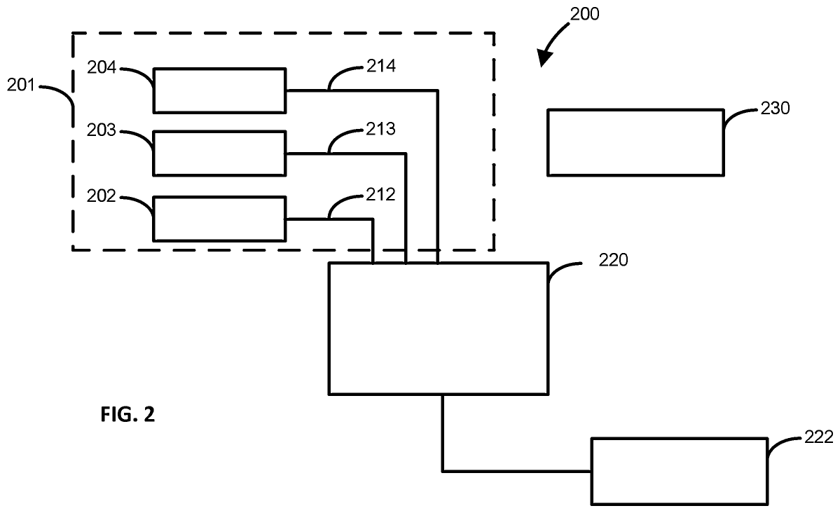

FIG. 2 is a schematic illustration of a semiconductor processing assembly 200 for selectively depositing oxide material on a first surface of a substrate according to the current disclosure. The semiconductor processing assembly 200 comprises one or more reaction chambers 220 constructed and arranged to hold the substrate, a precursor injector system 201 constructed and arranged to provide a first precursor and an oxygen precursor into the reaction chamber in a vapor phase. The semiconductor processing assembly 200 comprises a first precursor source 202 constructed and arranged to contain the first precursor, an oxygen source 203 constructed and arranged to contain the oxygen precursor, and a third reactant source 204 constructed and arranged to contain an optional catalyst. The assembly is constructed and arranged to provide the first precursor and the oxygen precursor, as well as the optional catalyst, via the precursor injector system 201 to the reaction chamber 220 to deposit oxide material on the first surface of the substrate. In the illustrated example, the semiconductor processing assembly 200 further includes an exhaust source 222, and a controller 230. The semiconductor processing assembly 200 may comprise one or more additional gas sources (not shown), such as an additional reactant source for a second metal precursor, an inert gas source, a carrier gas source and/or a purge gas source. The semiconductor processing assembly 200 can be used to perform a method as described herein.

The semiconductor processing assembly further comprises a first precursor source constructed and arranged to contain the first precursor, and an oxygen source constructed and arranged to contain the oxygen precursor. The semiconductor processing assembly is constructed and arranged to provide the first metal precursor and the oxygen precursor via the precursor injector system into the reaction chamber for selectively depositing metal oxide on the substrate.

In embodiments, in which blocking and/or passivation is performed in the same semiconductor processing assembly, the assembly may comprise the corresponding sources. Thus, in some embodiments, the semiconductor processing assembly further comprises one or more passivation sources, and the precursor injector system is constructed and arranged to provide one more passivation agents into the reaction chamber in a vapor phase before providing the first metal precursor into the reaction chamber.

Reaction chamber 202 can include any suitable reaction chamber, such as an ALD or CVD reaction chamber as described herein. The first precursor source 202 can include a vessel and a first precursor as described herein—alone or mixed with one or more carrier (e.g., inert) gases. An oxygen source 203 can include a vessel and an oxygen precursor as described herein—alone or mixed with one or more carrier gases. A third reactant source 204 can include a catalyst as described herein. For embodiments utilizing a second metal precursor, there may be a corresponding number of third additional reactant sources (not depicted in FIG. 2). Thus, although illustrated with three reactant sources 202-204, a semiconductor processing assembly 200 can include any suitable number of sources. Sources 202-204 can be coupled to reaction chamber 202 via lines 212-214, which can each include flow controllers, valves, heaters, and the like. In some embodiments, each of the first precursor in the first precursor source 202, the oxygen precursor in the oxygen source 203 and/or the catalyst in the third reactant source 204 may be independently heated or kept at ambient temperature. In some embodiments, a source vessel is heated so that a precursor or a reactant reaches a suitable temperature for vaporization

Exhaust source 222 can include one or more vacuum pumps.

Controller 230 includes electronic circuitry and software to selectively operate valves, manifolds, heaters, pumps and other components included in the semiconductor processing assembly 200. Such circuitry and components operate to introduce precursors, reactants and purge gases from the respective sources. Controller 230 can control timing of gas pulse sequences, temperature of the substrate and/or reaction chamber 202, pressure within the reaction chamber 202, and various other operations to provide proper operation of the semiconductor processing assembly 200. Controller 230 can include control software to electrically or pneumatically control valves to control flow of precursors, reactants and purge gases into and out of the reaction chamber 202. Controller 230 can include modules such as a software or hardware component, which performs certain tasks. A module may be configured to reside on the addressable storage medium of the control system and be configured to execute one or more processes. In some embodiments, a semiconductor processing assembly is disclosed, in which the assembly comprises a reaction chamber and a controller, wherein the controller is constructed and arranged for causing the system to execute a method according to the current disclosure.

Other configurations of semiconductor processing assembly 200 are possible, including different numbers and kinds of precursor and reactant sources. For example, a reaction chamber 202 may comprise more than one, such as two or four, deposition stations. Such a multi-station configuration may have advantages if, for example, blocking, passivation and/or activation treatment are to be performed in the same chamber. Further, it will be appreciated that there are many arrangements of valves, conduits, precursor sources, reactant sources and other gas sources that may be used to accomplish the goal of selectively and in coordinated manner feeding gases into reaction chamber 202. Further, as a schematic representation of a semiconductor processing assembly, many components have been omitted for simplicity of illustration, and such components may include, for example, various valves, manifolds, purifiers, heaters, containers, vents, and/or bypasses.

During operation of semiconductor processing assembly 200, substrates, such as semiconductor wafers (not illustrated), are transferred from, e.g., a substrate handling system to reaction chamber 202. Once substrate(s) are transferred to reaction chamber 202, one or more gases from gas sources, such as precursors, reactants, carrier gases, and/or purge gases, are introduced into reaction chamber 202.

In this disclosure, “gas” can include material that is a gas at normal temperature and pressure (NTP), a vaporized solid and/or a vaporized liquid, and can be constituted by a single gas or a mixture of gases, depending on the context. Precursors according to the current disclosure may be provided to the reaction chamber in gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

In the abbreviations of chemical formulas, Me stands for methyl, Et for ethyl, Pr for propyl, Bu for butyl, ⁱPr for isopropyl, ⁿPr for n-propyl, ^{s}Bu stands for sec-butyl, ^{t}Bu for tert-butyl, dmamp for 2-dimethylamino-2-methyl-1-propanolate; mmp for 1-methoxy-2-methyl-2-propoxide; acac for acetylacetonato; dpguan for N,N′-diisopropyl-2-dimethylamidoguanidinato; FMD for formamidinato; triaz for 1,3-diisopropyltriazenide; edpa for bis(N-ethoxy-2,2-dimethyl propanamido; DAD for N,N-bis(tertbutyl)ethene-1,2-diaminato; CHT for Cycloheptatrienyl; mmp for 1-methoxy-2-methyl-2-propoxy; edpa for N-ethoxy-2,2-dimethylpropanamido; and TMEA for tris[2-(methylamino)ethyl]aminato.

The subject-matter of the present disclosure includes all novel and nonobvious combinations and sub-combinations of the various methods and assemblies, and other features, functions, acts, and/or properties disclosed herein, as well as any and all equivalents thereof.

1. A method of selectively depositing an oxide material layer on a first surface of a substrate relative to a second surface of the substrate, the method comprising:
providing a substrate comprising the first surface and the second surface in a reaction chamber;
providing a first precursor into the reaction chamber in a vapor phase; and
providing an oxygen precursor comprising a hydroxyl group into the reaction chamber in vapor phase to form an oxide material layer on the first surface.

2. The method of claim 1, wherein the second surface comprises a polyimide-comprising passivation layer.

3. The method of claim 1, wherein the first surface is a dielectric surface.

4. The method of claim 3, wherein the first surface comprises silicon.

5. The method of claim 1, wherein the method comprises providing a metal or metalloid catalyst into the reaction chamber.

6. The method of claim 5, wherein the catalyst is a metal halide, organometallic compound or metalorganic compound.

7. The method of claim 1, wherein the oxygen precursor is an alcohol comprising from 1 to 6 carbon atoms.

8. The method of claim 7, wherein the oxygen precursor is a secondary or tertiary alcohol.

9. The method of claim 1, wherein the first precursor comprises an alkoxy group.

10. The method of claim 9, wherein the oxide material layer comprises silicon oxide, and the first precursor is an alkoxy silane precursor.

11. The method of claim 9, wherein the oxide material of the oxide material layer is a metal oxide, and the first precursor comprises a metal alkoxide.

12. The method of claim 11, wherein the first precursor comprises a metal atom, an alkyl group and an alkoxide group.

13. The method of claim 11, wherein the metal of the first precursor is selected from a group consisting of Al, Ga and In.

14. The method of claim 13, wherein the first precursor is selected from a group consisting of aluminum propoxide (Al(OⁿPr)₃), aluminum isopropoxide (Al(OⁱPr)₃), aluminum sec-butoxide (Al(O^{s}Bu)₃), aluminum ethoxide (Al(OEt)₃), Al(NⁱPr₂)₂(C₃H₆NMe₂) dimethylaluminum isopropoxide (AlMe₂OⁱPr), dimethylgallium isopropoxide (GaMe₂OⁱPr), and In(dmamp)₂(OiPr).

15. The method of claim 1, wherein the first precursor comprises a cyclopentadienyl group.

16. The method of claim 15, wherein the first precursor is a heteroleptic precursor comprising a group 3 metal, at least one cyclopentadienyl ligand, and at least one amidinato ligand.

17. The method of claim 16, wherein the amidinato ligand comprises an alkylacetamidinato ligand.

18. The method of claim 17, wherein the alkylacetamidinato ligand is a dialkylacetamidinato ligand.

19. The method of claim 1, wherein the oxide material of the oxide material layer is a metal oxide, and wherein the metal of the metal oxide is selected from a group consisting of scandium (Sc), yttrium (Y), lanthanum (La) and cerium (Ce).

20. The method of claim 1, wherein the method is a cyclic process, and a deposition cycle of the cyclic process comprises providing the first precursor and the oxygen precursor into the reaction chamber.

21. The method of claim 1, wherein the oxide material layer is deposited in a substantially water-free environment.

22. A semiconductor processing assembly for selectively depositing an oxide material layer on a substrate, the assembly comprising:
one or more reaction chambers constructed and arranged to hold the substrate;
a precursor injector system constructed and arranged to provide a first precursor and an oxygen precursor into the reaction chamber in a vapor phase;
a first precursor source constructed and arranged to contain the first precursor; and
an oxygen source constructed and arranged to contain the oxygen precursor;
wherein the assembly is constructed and arranged to provide the first metal precursor and the oxygen precursor via the precursor injector system into the reaction chamber for selectively depositing metal oxide on the substrate.
